(19) United States
(12) Patent Application Publication
(10) Pub. No.: US 2011/0056564 A1
(43) Pub. Date: Mar. 10, 2011

(54) NANOPARTICLES AND METHODS OF MAKING AND USING

(76) Inventors: Brian A. Korgel, Round Rock, TX (US); Matthew G. Panthani, Austin, TX (US); Brian W. Goodfellow, Austin, TX (US); Vahid A. Akhavan, Austin, TX (US); Bonil Koo, Austin, TX (US)

(21) Appl. No.: 12/991,518

(22) PCT Filed: May 7, 2009
(86) PCT No.: PCT/US09/43069

§ 371 Date: Nov. 8, 2010

Related U.S. Application Data
(60) Provisional application No. 61/052,003, filed on May 9, 2008.

(51) Int. Cl. H01L 31/0264; G02F 1/355; H01B 1/02; B05D 5/12; C01B 17/00; C01B 19/00; H01L 31/0272

(52) U.S. Cl. 136/265; 252/582; 252/512; 252/500; 427/74; 427/76; 423/511; 423/508; 136/252; 977/773

(57) ABSTRACT

A nanoparticle composition is disclosed comprising a copper indium gallium selenide, a copper indium sulfide, or a combination thereof. Also disclosed is a layer comprising the nanoparticle composition. A photovoltaic device comprising the nanoparticle composition and/or the absorbing layer is disclosed. Also disclosed are methods for producing the nanoparticle compositions, absorbing layers, and photovoltaic devices described herein.

### TECHNICAL FIELD

The present disclosure relates to nanoparticle materials, and specifically to the use of nanoparticle materials in devices.

### TECHNICAL BACKGROUND

Copper indium gallium selenide (CIGS) and copper indium sulfide can be useful as light-absorbing material in photovoltaic devices due to, for example, their match to the solar spectrum and high optical absorption coefficients. The efficiency of most single junction thin-film solar cells is limited, and even those employing a CIGS absorber layer can have a solar energy conversion of about 20% or less. CIGS can be an inexpensive material with good long-term stability that can improve with time. High efficiency devices can be made when a CIGS material is deposited as a polycrystalline film, in contrast to other materials that can require a single crystal absorber material for high efficiency photoconversion.

CIGS films for photovoltaics are currently deposited onto substrates by a coevaporation process, in which copper, indium, and gallium metal are first deposited, then reacted with Se vapor or H₂Se to convert the deposited materials to CIGS. This deposition approach can be expensive and the CIGS stoichiometry can be difficult to control when trying to deposit the films over large areas.

Solution-based methods have been developed to synthesize colloidal nanocrystals of many different materials, including metals, and Group II-VI, III-V, 1-VI, and IV semiconductors. Colloidal CdSe and CdTe nanocrystals have been used to form functional photovoltaic devices with reasonable light energy conversion efficiencies; however, many Group II-VI semiconductors that would be useful for photovoltaic devices, such as CdTe for example, contain toxic Pb, Cd, and Hg, which make them undesirable for widespread commercialization.

Synthetic procedures for colloidal CuInS₂ and CIGS nanocrystals have been reported in the literature, but these procedures typically produce particles with relatively low yield, poor crystallinity, and contamination with multiple phases. Thus, there is a need to address the aforementioned problems and other shortcomings associated with traditional CIGS synthesis and their incorporation into devices. These needs and other needs are satisfied by the compositions and methods of the present disclosure.

### SUMMARY

In accordance with the purpose(s) of the invention, as embodied and broadly described herein, this disclosure, in one aspect, relates to nanoparticle materials, such as, for example, copper indium gallium selenide and copper indium sulfide (CIGS nanoparticles), methods of making nanoparticle materials, and to the use of such nanoparticles in devices, such as, for example, photovoltaic devices.

In one aspect, the present disclosure provides an absorbing layer comprising a nanocrystal comprising at least one of a copper indium gallium selenide, a copper indium sulfide, or a combination thereof.

In another aspect, the present disclosure provides a nanocrystal comprising at least one of a copper indium gallium selenide, a copper indium sulfide, or a combination thereof, wherein the nanocrystal is capable of being drop-cast, dip-coated, spin-coated, sprayed, airbrushed, and/or printed onto a substrate.

In yet another aspect, the present disclosure provides a photovoltaic device comprising the absorbing layer described above.

In yet another aspect, the present disclosure provides a method for making a nanocrystal composition, the method comprising any one or more of the steps disclosed herein.

### BRIEF DESCRIPTION OF THE FIGURES

The accompanying figures, which are incorporated in and constitute a part of this specification, illustrate several aspects and together with the description serve to explain the principles of the invention.

FIG. 1 illustrates TEM images of copper indium sulfide nanocrystals synthesized in accordance with the various aspects of the present disclosure using (a-b) 6:1 oleylamine (OLA):(Cu+In) ratio (inset HRTEM image) resulting in ˜8 nm nanocrystals, and (c-d) 3:1 OLA:(Cu+In) ratio resulting in ˜12 mm nanocrystals.

FIG. 2 illustrates Powder XRD data for 8 nm CuInS₂ nanocrystals having a chalcopyrite structure consistent with that of bulk CuInS₂, in accordance various aspects of the present disclosure.

FIG. 3 illustrates TEM images of (a-b) ˜15 nm CuInSe₂ nanocrystals and (c-d) High Resolution TEM (HRTEM) images, indicating the crystallinity of nanocrystals produced in accordance with the various aspects of the present disclosure.

FIG. 4 illustrates Powder XRD data for (a) CuInSe₂ (b) CuIn_{0.75}Ga_{0.25}Se₂ (c) CuIn_{0.5}Ga_{0.5}Se₂ (d) CuGaSe₂ nanocrystals, in accordance with various aspects of the present disclosure.

FIG. 5 illustrates TEM images of CuInSe₂ nanoprisms with (a) honeycomb lattices and (b) close-packed assembly, along with lower resolution images thereof (c and d, respectively), in accordance with various aspects of the present disclosure.

FIG. 6 illustrates HRTEM images of CuInSe₂ nanoprisms exhibiting honeycomb lattices, in accordance with various aspects of the present disclosure.

FIG. 7 illustrates an SEM image of CuInSe₂ nanoprisms showing tetrahedron edges, in accordance with various aspects of the present disclosure.

FIG. 8 illustrates XRD data for CuInSe₂ nanoprisms, in accordance with various aspects of the present disclosure.

FIG. 9 illustrates the UV-visible absorbance spectra of a CuInSe₂ nanoprism composition, in accordance with various aspects of the present disclosure.

FIG. 10 illustrates an aging effect on triangular CuInSe₂ nanoprisms, in accordance with various aspects of the present disclosure.

FIG. 11 illustrates a CIS film dropped from 5 mg/ml in tetrachloroethylene (a-c), and a CIS film dropped from 5 mg/ml in chloroform (d), in accordance with various aspects of the present disclosure.

FIG. 12 illustrates the effect of nanoparticle solution concentration on resulting film thickness for a solution of CuInSe₂ nanoparticles in tetrachloroethylene (a) and cross sectional SEM of one of the films (b), in accordance with various aspects of the present disclosure.

FIG. 13 illustrates (a) the effect of annealing temperature on resistivity, and XRD patterns as a function of annealing temperature under (b) nitrogen, (c) forming gas, and (d) air, in accordance with various aspects of the present disclosure.

FIG. 14 illustrates the selenium content of exemplary films after annealing up to 500° C. under different environments, in accordance with various aspects of the present disclosure.

FIG. 15 illustrates (a) resistivity and (b) oxygen content of UV-ozone and oxygen plasma treated films, in accordance with various aspects of the present disclosure.

FIG. 16 illustrates an inkjet printer in operation printing a test wafer, in accordance with various aspects of the present disclosure.

FIG. 17 illustrates an (A) exemplary device geometry, and (B) a picture of a superstrate device geometry, in accordance with various aspects of the present disclosure.

FIG. 18 illustrates current-potential (IV) characteristics for CIGS devices built in accordance with various aspects of the present disclosure.

FIG. 19 illustrates TEM images of copper indium sulfide nanocrystals (CuInS₂), in accordance with various aspects of the present disclosure.

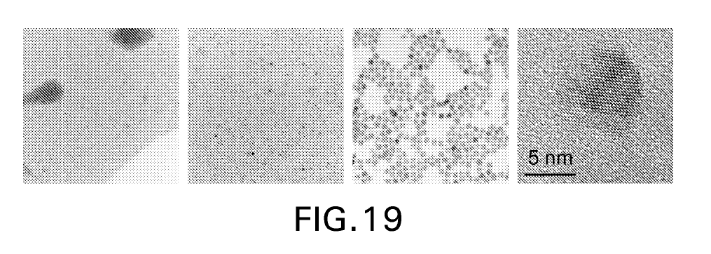

FIG. 20 illustrates an SEM image of a CIS nanocrystal film, in accordance with various aspects of the present disclosure.

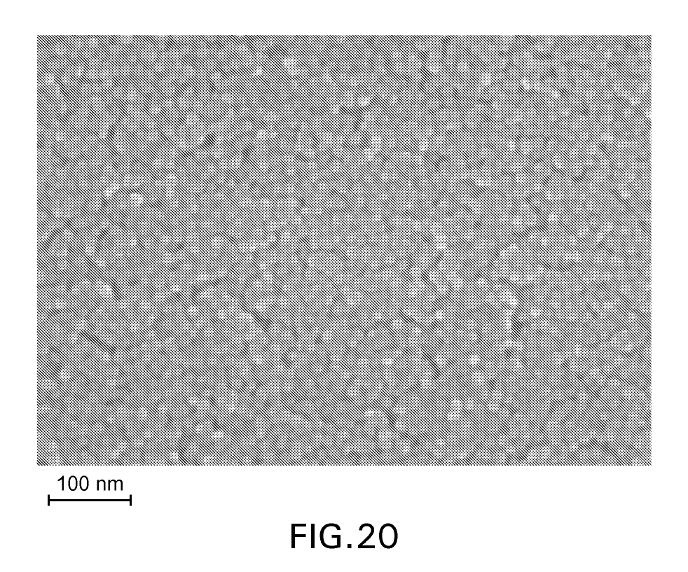

FIG. 21 illustrates an image of a CIS nanoparticle film dropcast from chloroform, in accordance with various aspects of the present disclosure.

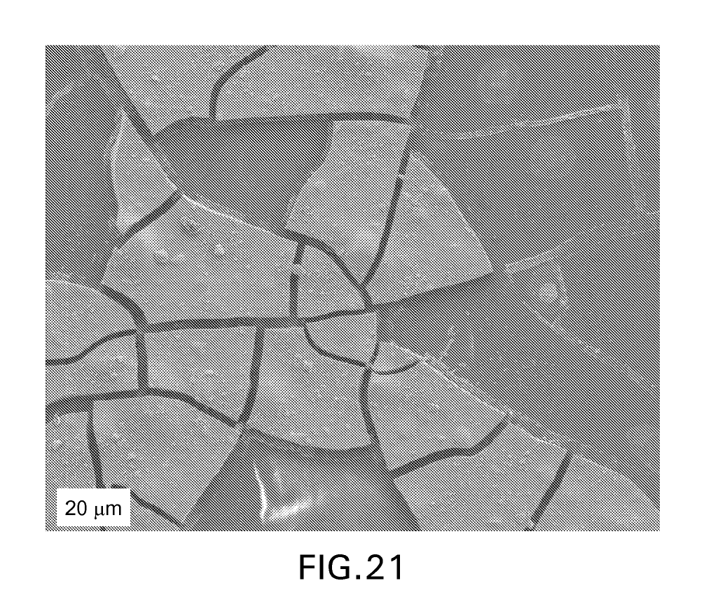

FIG. 22 illustrates an image of a CIS nanoparticle film produced through dip coating in chloroform, in accordance with various aspects of the present disclosure.

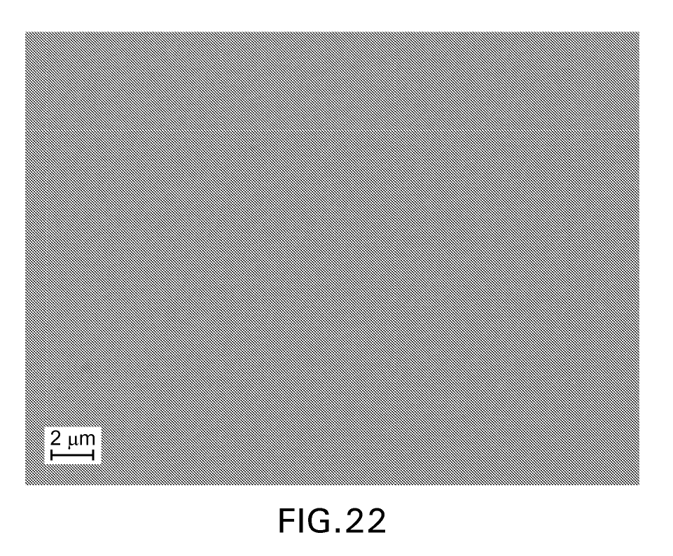

FIG. 23 is a height profile graph for a CIS nanoparticle film produced through dip coating in chloroform, in accordance with various aspects of the present disclosure.

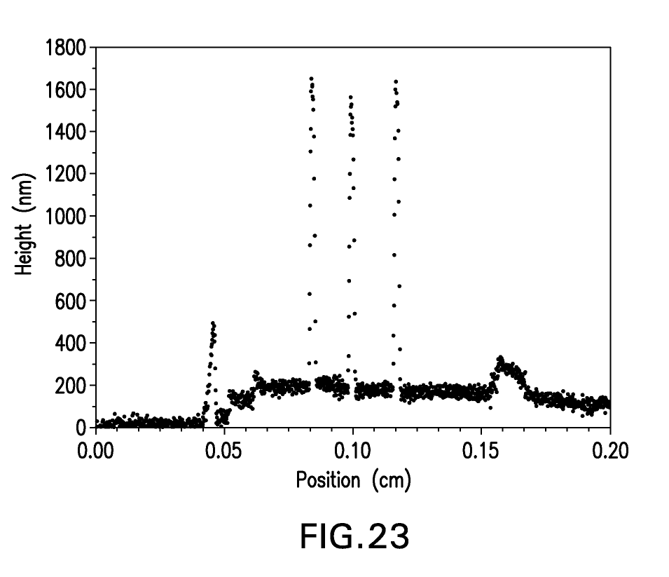

FIG. 24 illustrates an image of a CIS nanoparticle film produced through dip coating in tetrachloroethylene, in accordance with various aspects of the present disclosure.

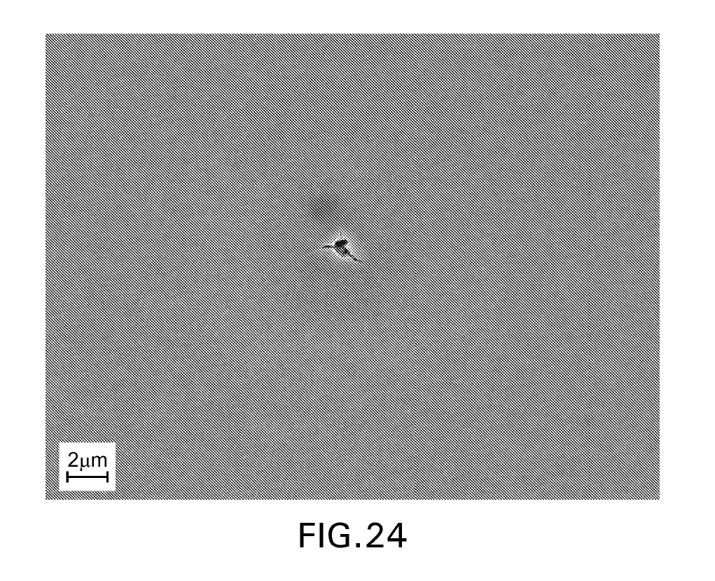

FIG. 25 is a height profile graph for a CIS nanoparticle film produced through dip coating in tetrachloroethylene, in accordance with various aspects of the present disclosure.

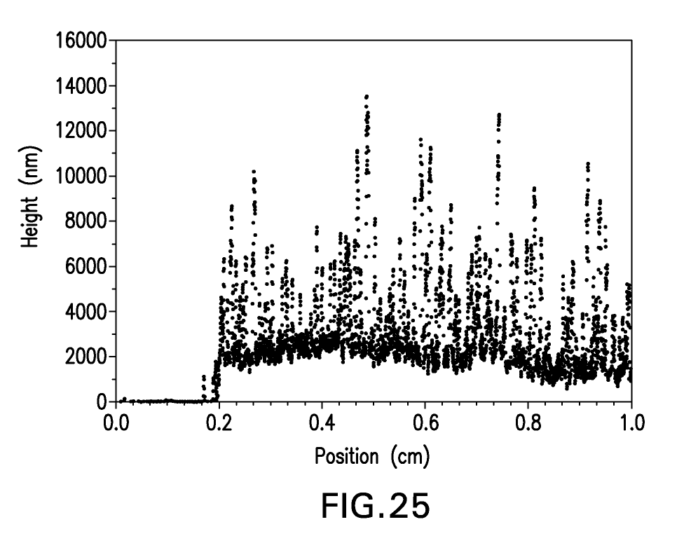

FIG. 26 illustrates an image of a CIS nanocrystal coated substrate prepared by inkjet printing, in accordance with various aspects of the present disclosure.

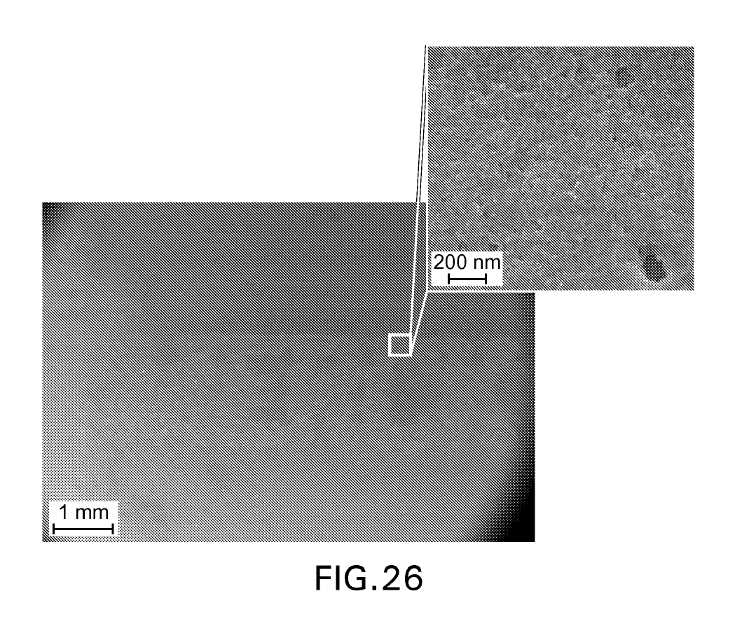

FIG. 27 illustrates a four-point probe graph of electrical resistivity for UV-Ozone treated CIGS nanoparticles, in accordance with various aspects of the present disclosure.

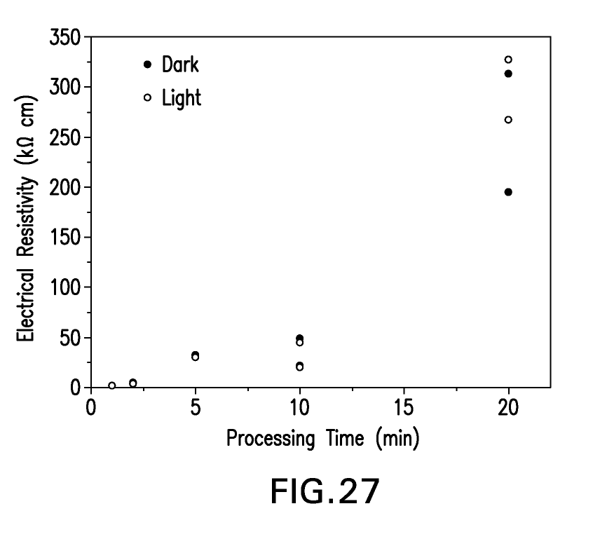

FIG. 28 illustrates x-ray photoelectron spectroscopy data for UV-Ozone treated CIGS nanoparticles at different UV-Ozone treatment times, in accordance with various aspects of the present disclosure.

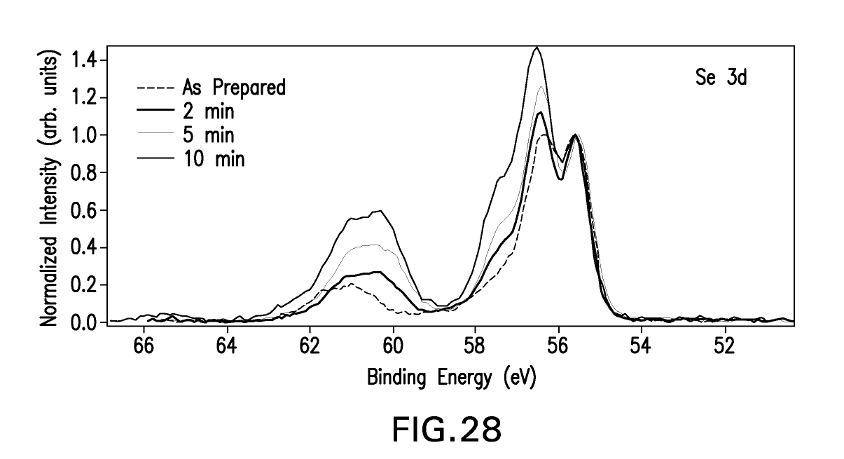

FIG. 29 illustrates XRD data for UV-Ozone treated CIGS nanoparticles at different UV-Ozone treatment times, in accordance with various aspects of the present disclosure.

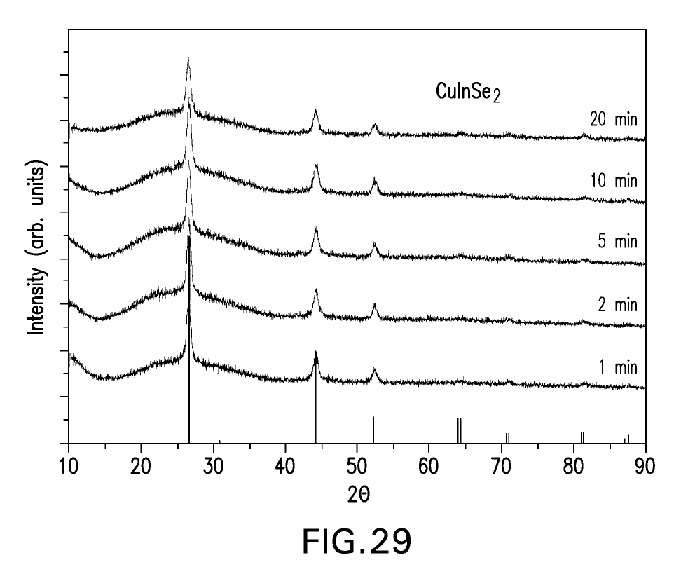

FIG. 30 illustrates EDS data for UV-Ozone treated CIGS nanoparticles at different UV-Ozone treatment times, in accordance with various aspects of the present disclosure.

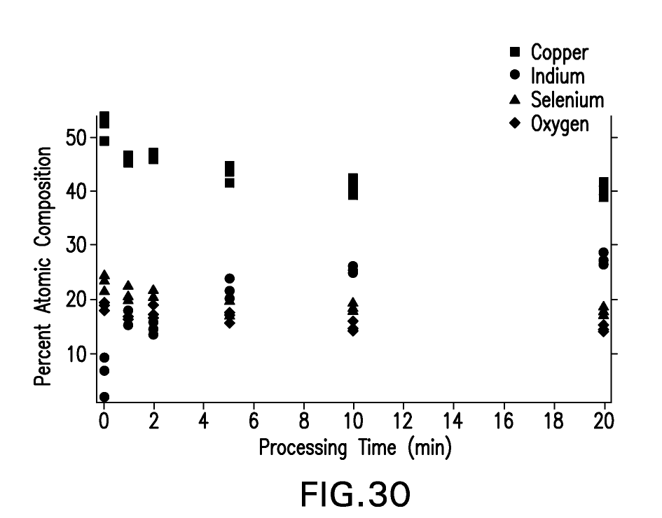

FIG. 31 illustrates a four-point probe graph of electrical resistivity for forming gas annealed CIGS nanoparticles, in accordance with various aspects of the present disclosure.

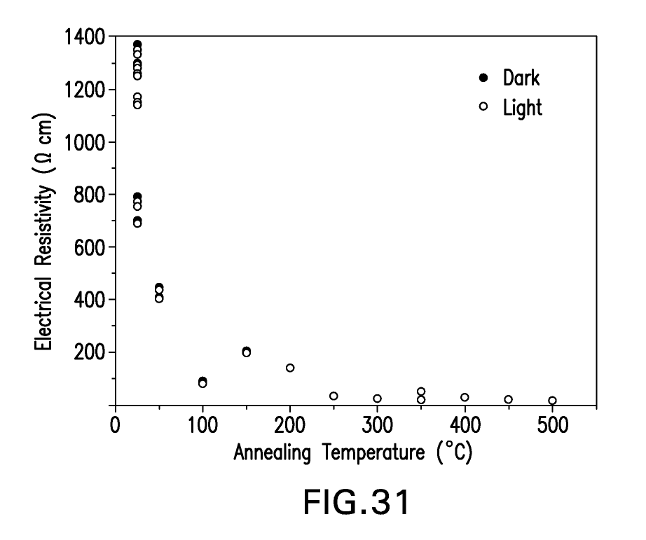

FIG. 32 illustrates XPS data for forming gas annealed CIGS nanoparticles at different temperatures, in accordance with various aspects of the present disclosure.

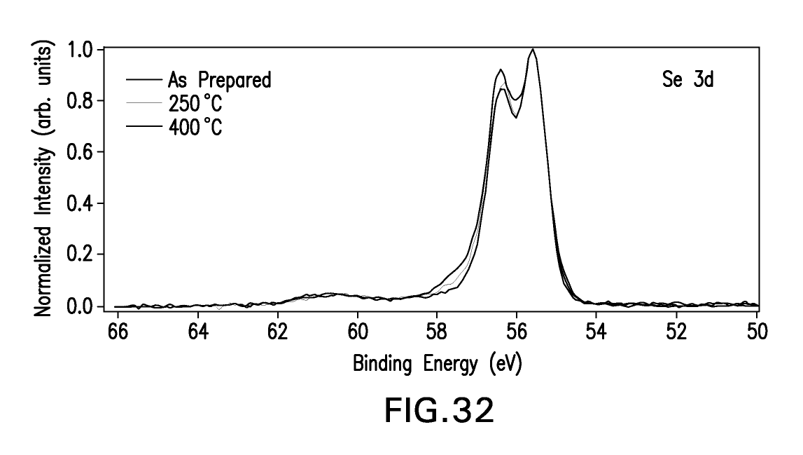

FIG. 33 illustrates XRD data of forming gas annealed nanoparticles at different temperatures, in accordance with various aspects of the present disclosure.

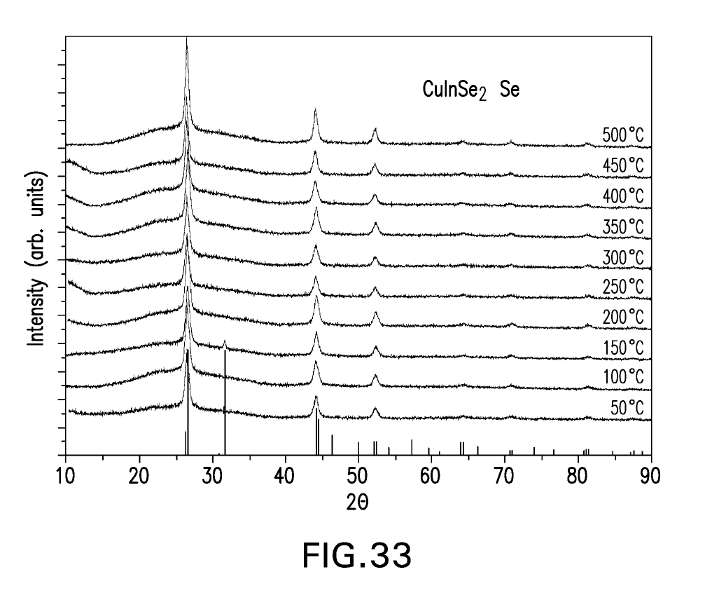

FIG. 34 illustrates EDS data of forming gas annealed nanoparticles at different annealing temperatures, in accordance with various aspects of the present disclosure.

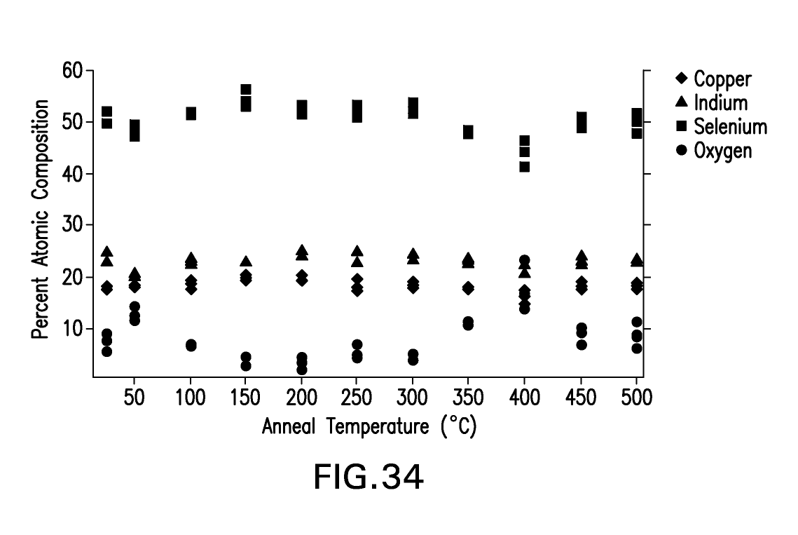

Additional aspects of the invention will be set forth in part in the description which follows, and in part will be obvious from the description, or can be learned by practice of the invention. The advantages of the invention will be realized and attained by means of the elements and combinations particularly pointed out in the appended claims. It is to be understood that both the foregoing general description and the following detailed description are exemplary and explanatory only and are not restrictive of the invention, as claimed.

### DESCRIPTION

The present invention can be understood more readily by reference to the following detailed description of the invention and the Examples included therein.

Before the present compounds, compositions, articles, systems, devices, and/or methods are disclosed and described, it is to be understood that they are not limited to specific synthetic methods unless otherwise specified, or to particular reagents unless otherwise specified, as such can, of course, vary. It is also to be understood that the terminology used herein is for the purpose of describing particular aspects only and is not intended to be limiting. Although any methods and materials similar or equivalent to those described herein can be used in the practice or testing of the present invention, example methods and materials are now described.

### Definitions

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, example methods and materials are now described.

As used in the specification and the appended claims, the singular forms “a,” “an” and “the” include plural referents unless the context clearly dictates otherwise. Thus, for example, reference to “a solvent” includes mixtures of two or more solvents.

Ranges can be expressed herein as from “about” one particular value, and/or to “about” another particular value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. It is also understood that each unit between two particular units are also disclosed. For example, if 10 and 15 are disclosed, then 11, 12, 13, and 14 are also disclosed.

As used herein, the terms “optional” or “optionally” means that the subsequently described event or circumstance can or can not occur, and that the description includes instances where said event or circumstance occurs and instances where it does not.

Disclosed are the components to be used to prepare the compositions of the invention as well as the compositions themselves to be used within the methods disclosed herein. These and other materials are disclosed herein, and it is understood that when combinations, subsets, interactions, groups, etc. of these materials are disclosed that while specific reference of each various individual and collective combinations and permutation of these compounds can not be explicitly disclosed, each is specifically contemplated and described herein. For example, if a particular compound is disclosed and discussed and a number of modifications that can be made to a number of molecules including the compounds are discussed, specifically contemplated is each and every combination and permutation of the compound and the modifications that are possible unless specifically indicated to the contrary. Thus, if a class of molecules A, B, and C are disclosed as well as a class of molecules D, E, and F and an example of a combination molecule, A-D is disclosed, then even if each is not individually recited each is individually and collectively contemplated meaning combinations, A-E, A-F, B-D, B-E, B-F, C-D, C-E, and C-F are considered disclosed. Likewise, any subset or combination of these is also disclosed. Thus, for example, the sub-group of A-E, B-F, and C-E would be considered disclosed. This concept applies to all aspects of this application including, but not limited to, steps in methods of making and using the compositions of the invention. Thus, if there are a variety of additional steps that can be performed it is understood that each of these additional steps can be performed with any specific embodiment or combination of embodiments of the methods of the invention.

Each of the materials disclosed herein are either commercially available and/or the methods for the production thereof are known to those of skill in the art.

It is understood that the compositions disclosed herein have certain functions. Disclosed herein are certain structural requirements for performing the disclosed functions, and it is understood that there are a variety of structures that can perform the same function that are related to the disclosed structures, and that these structures will typically achieve the same result.

Various chemical abbreviation known in the art are recited herein with respect to components, precursors, and other compounds. For example, the abbreviation “(acac)” is used to refer to acetyl acetonate. One of skill in the art could readily understand any chemical abbreviations utilized with respect to such components, precursors, and other compounds.

As used herein, the term “ink” is intended to refer to a dispersion of nanoparticles within a liquid, such as, for example, a solvent or vehicle system, unless specifically stated to the contrary.

### Nanoparticles

In one aspect, a nanoparticle of the present invention can comprise an inorganic material, such as, for example, Cu. Other components, such as other inorganic elements and/or organic ligands and/or dopants can, in various aspects, optionally be present. Materials that can be incorporated into nanoparticles include, without limitation, indium, gallium, zinc, and selenide, sodium, and sulfide. Exemplary nanoparticles can correspond to the formulas CuInSe₂, CuInS₂, CuInₓGa₁₋ₓSe₂, CnInTe₂, CuGaₓIn₁₋ₓTe₂, CuGaₓIn₁₋ₓTe₂, Cu₂ZnSnS₂, Cu₂ZnSnS₄, Cu₂ZnSnSe₄, or Cu(InₓGa₁₋ₓ)Se₂, wherein x is a whole number or fraction that can be determined by compositional analysis and generally depends on the stoichiometry of the various starting materials. In one aspect, a nanoparticle can comprise a ternary composition, such as, for example, CuInSe₂. In another aspect, a nanoparticle can comprise a quaternary composition, such as, for example, Cu₂ZnSnS₄.

The composition of a nanoparticle corresponding to a formula, Cu(InₓGa₁₋ₓ)Se₂, can comprise various compositional ratios of the elements in the formula. It should be appreciated that the composition of such a nanoparticle can be tuned by adjusting the relative amounts of each element, for example, In and Ga, during synthesis. For example, x can be a whole integer selected from 0 and 1. Or, in the alternative, x can be a fraction (i.e. a number greater than 0 and less than 1). For example, x can be 0.2, 0.3, 0.4, 0.5, 0.6, 0.7, 0.8, or 0.9. Specific examples can include nanoparticles corresponding to the formula, Cu(InₓGa₁₋ₓ)Se₂, wherein x is 0, 0.75, 0.50, and 1 as determined by, for example, XRD, with corresponding values of 0, 0.79, 0.51, and 1 as determined by, for example, EDS. The amount of Ga (1-x) can be determined from x. For example, if x is 0.75, then 1-x is 0.25. It should be appreciated that the various methods of the present invention provide the ability to adjust the stoichiometry of any combination of elements within a mixture and thus, provide a wide range of nanoparticle compositions.

The nanoparticles of the present invention can be prepared by a variety of methods. It should be understood that the specific order of steps and/or contacting components in the recited methods can vary, and the present invention is not intended to be limited to any particular order, sequence, or combination of individual components or steps. One of skill in the art, in possession of this disclosure, could readily determine an appropriate order or combination of steps and/or components to produce a nanoparticle.

In one aspect, a precursor of each of the desired elements to be present in the nanoparticle can be contacted together with an aliphatic amine to form a nanoparticle. In other aspects, any one or more of the precursors can be contacted together to form one or more mixtures. In such an aspect, any given mixture can comprise a solvent. In addition, any given mixture can optionally be degassed and/or sparged with an inert gas. Further, any given mixture or combination of mixtures can be heated.

An aliphatic amine can be any aliphatic amine suitable for use in the preparation of nanoparticles. In one aspect, the aliphatic amine can be an alkyl amine. In another aspect, an aliphatic amine can be oleylamine. In another aspect, the specific number of carbons in an aliphatic amine can vary, and the present invention is not intended to be limited to any particular aliphatic amine, such as, for example, an oleylamine. Exemplary chain lengths can comprise, but are not limited to, 10, 11, 12, 13, 14, 15, 16, 17, 18, 19, 20, 21, 22, 23, 24, 25, 26, 27, 28, 29, or 30 carbons. In one aspect, an aliphatic amine has a high boiling point.

In one aspect, the nanoparticles can be prepared by contacting a copper precursor, an indium precursor, sulfur, and/or a sulfur containing species, and an aliphatic amine. In one aspect, an aliphatic amine can be a component of a solvent. In a specific aspect, an aliphatic amine can be oleylamine. In other aspects, at least a portion of the copper precursor, indium precursor, sulfur and/or sulfur containing species can be degassed and/or sparged with an inert gas. In yet another aspect, at least two of the copper precursor, indium precursor, and sulfur and/or sulfur containing species can be contacted separate from any remaining components prior to contacting with an aliphatic amine. In another aspect, at least one of the mixtures can optionally be heated after or during contacting.

In one aspect, the nanoparticles are prepared by a solution based method, wherein a plurality of precursors can be mixed and the resulting solution deposited onto a substrate. In one aspect, a copper precursor and an indium precursor are contacted with a solvent to form a first mixture; and sulfur and/or a sulfur containing species are separately contacted with either the same or a different solvent to form a second mixture, and then degassing and/or sparging each of the first and second mixture with an inert gas, and then contacting an aliphatic amine with the first mixture; heating at least one of the first mixture and/or the second mixture, and then contacting the first mixture and the second mixture to form a nanoparticle composition. In other aspects, each of the steps can be performed in a different combination and/or different order. For example, each of a copper precursor, an indium precursor, and sulfur and/or a sulfur containing species can be mixed with the same or different solvents. The specific methods of contacting, temperatures, and degree of mixing can vary depending upon the specific components and desired properties of the resulting nanoparticles.

In another aspect, a copper precursor, an indium precursor, a gallium precursor, a selenium precursor, and an aliphatic amine can be contacted to form a nanoparticle. In still another aspect, at least two of the copper precursor, an indium precursor, a gallium precursor, a selenium precursor can be contacted separate from any remaining components prior to contacting with the aliphatic amine. In a specific aspect, the copper precursor, indium precursor, gallium precursor, and selenium precursor are contacted prior to contacting with an aliphatic amine. In still another aspect, one or more precursor components, such as, for example, a selenium precursor can be contacted with a mixture of the remaining components. It should be noted that for any of the recited methods and variations thereof, it is not necessary that all of a precursor be contacted simultaneously and that one or more portions of any precursor can be contacted at a given time and the remaining portions be contacted at other times prior to, concurrent with, or subsequent to any other step or contacting.

In another aspect, a copper precursor, an indium precursor, a gallium precursor, and a selenium precursor can be contacted to form a mixture, and then the mixture can be contacted and/or mixed with an aliphatic amine. The resulting mixture can then be degassed and/or sparged with an inert gas, such as, for example, nitrogen, argon, or a combination thereof, and then heated for form a nanoparticle composition.

In yet another aspect, a copper precursor, an indium precursor, and a gallium precursor can be contacted to form a mixture, and then the mixture can be contacted with an aliphatic amine. The resulting mixture can be degasses and/or sparged with an inert gas, and then heated. After heating, the mixture can be contacted with a selenium precursor to form a nanoparticle composition.

The precursors for each component can vary and the present invention is not intended to be limited to any particular precursor materials. In one aspect, a precursor can comprise any compound containing the specific element for which the compound is a precursor. For example, in one aspect, a copper precursor can comprise any copper is containing compound; a selenium precursor can comprise any selenium containing compound; an indium precursor can comprise any indium containing compound; and a gallium precursor can comprise any gallium containing compound. One of skill in the art, in possession of this disclosure, could readily select an appropriate precursor material to produce a desired nanoparticle. In one aspect, a copper precursor can comprise Cu(acac)₂, CuCl, a copper containing salt, a copper containing organometallic compound, or a combination thereof. In another aspect, an indium precursor can comprise In(acac)₃, InCl₃, an indium containing salt, an indium containing organometallic compound, or a combination thereof. In yet another aspect, a selenium precursor comprises at least one of selenium, selenourea, bis(trimethylsilyl)selenide, or a combination thereof. In still other aspects, a gallium precursor can comprise GaCl₃, Ga(acac)₃, a gallium containing salt, a gallium containing organometallic compound, or a combination thereof.

Other specific methods and combinations are recited herein and are intended to be included in the present invention, together with other unrecited combination and variations. After formation, one or more nanoparticles can optionally be purified by precipitation with a solvent.

In one aspect, one or more of the nanoparticles can comprise a uniform or substantially uniform composition. In such an aspect, the one or more nanoparticles having the same or substantially the same stoichiometry and chemical composition throughout the structure of the nanoparticles. In such aspect, small variations in stoichiometry and/or the presence of contaminants and/or impurities are not intended to render a portion of the nanoparticle as not uniform. In another aspect, one or more of the nanoparticles does not comprise a core having a different chemical composition than a remaining portion of the nanoparticle.

Nanoparticles of the present invention can comprise any shape and size appropriate for a desired application, such as, for example, a photovoltaic application. It should be appreciated that nanoparticle shapes can depend on the mode of synthesis, as well as any post-treatment and/or aging. Thus, a variety of shapes are contemplated depending on the conditions under which a nanoparticle is made and/or stored. Exemplary nanoparticles can have shapes including, but not limited to, triangular, prism, tetragonal, or a combination thereof. In a specific aspect, at least a portion of the nanoparticles comprise a triangular shape. In another aspect, at least a portion of the nanoparticles comprise a prism or prismatic shape. In yet another aspect, at least a portion of the nanoparticles comprise a tetragonal shape. In still further aspects, at least a portion of the nanoparticles comprise a tetrahedron shape. In one aspect, all or a portion of the nanoparticles do not comprise a flake. In other aspects, nanoparticles can have a chalcopyrite structure. It should be appreciated that a given batch of nanoparticles can have a shape distribution (i.e. various nanoparticles within a synthetic batch can comprise different shapes).

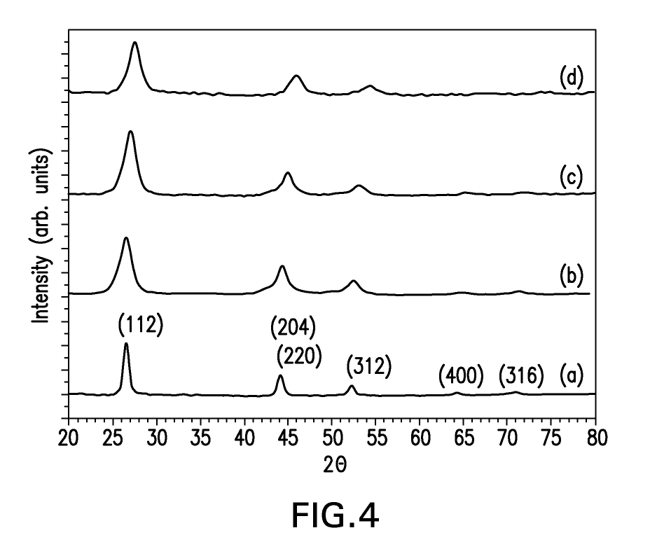

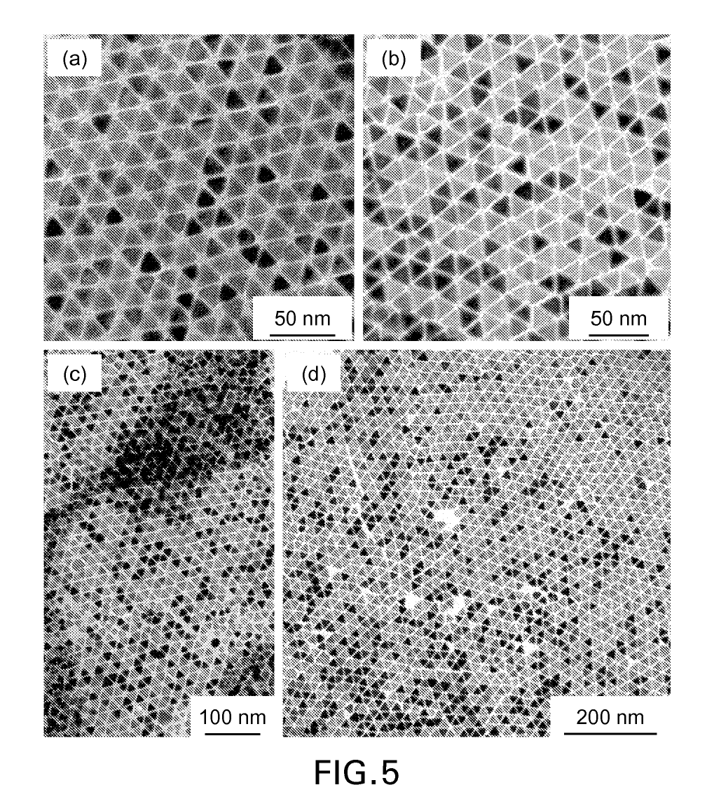

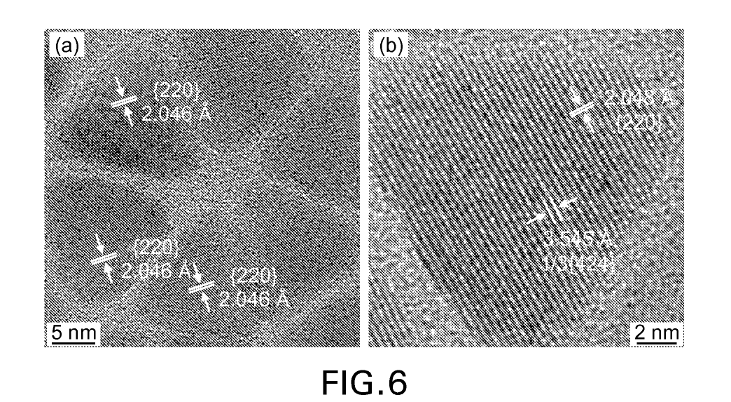

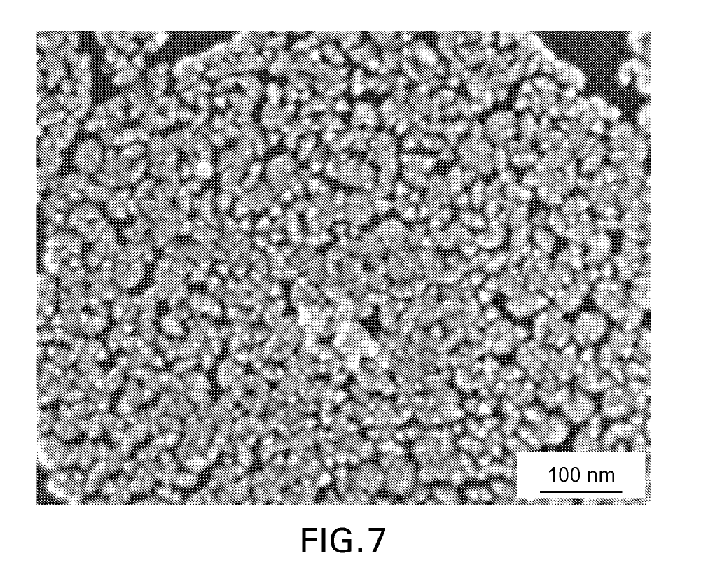

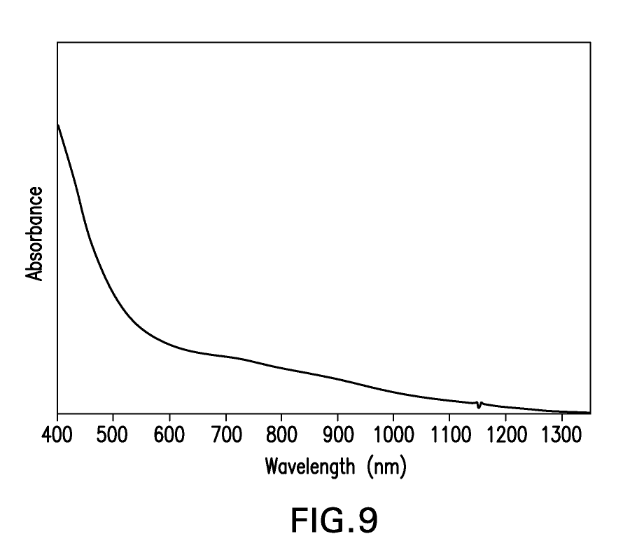

FIG. 5 shows TEM images of the CuInSe₂ triangular nanoprisms with two different types of ordering. Such nanoparticles can have the same or different assembly along particle shapes. FIGS. 5a and 5c show nanoprisms with smooth edges, which comprise honeycomb lattices, while FIGS. 5b and 5d show nanoprisms having sharp edges with close-packing. Average edge-to-edge length of the triangular nanoprisms can be about 16.3 nm for honeycomb structure (FIGS. 5a and 5c) and about 17.7 nm for close-packing assembly (FIGS. 5b and 5d). HRTEM images show crystalline lattices of the CuInSe₂ triangular nanoprisms with honeycomb ordering in FIG. 6. FIG. 6a reveals that the nanoprisms coordinating the ordering in one honeycomb have the same crystallographic orientation. The SEM image in FIG. 7 shows many sharp edges of tetrahedrons, indicating that the triangular shapes of the synthesized CuInSe₂ particles were prisms. XRD patterns (FIG. 4) and UV-visible absorbance (FIG. 9) from the triangular nanoprisms synthesized confirmed that they were CuInSe₂ (E_{g}=˜1 eV) having tetragonal crystal structures. In one aspect, a nanoparticle can be crystalline or substantially crystalline.

In one aspect, a nanoparticle can comprise a coating over all or a portion of its surface. A coating, if present, can be useful to, for example, assist in dispersion of the nanoparticle in an ink or solvent, assist in the formation of a film or layer comprising the nanoparticle, and/or to protect the composition and/or structure of a nanoparticle during the formation of a film or layer, and/or during use. A coating, if present, can comprise an organic material, an inorganic material, or a combination thereof. In one aspect, a coating comprises an organic material. In another aspect, a coating comprises an inorganic material. In a specific aspect, a coating comprises a metal. In yet another aspect, a nanoparticle does not comprise a coating. A two or more nanoparticles are not required to comprise the same composition and/or coating, and combinations wherein, for example, a portion of the nanoparticles comprise a coating, and wherein; for example, two coating materials are used, are considered to be part of the invention. A coating, if present, can comprise an electrically conductive material, such as, for example, a conjugated molecule, and/or an electrically insulating coating, such as, for example, an alkane and/or phenyl containing coating.

In one aspect, a coating, if present, can comprise a capping ligand. In various aspects, a capping ligand can comprise a nitrogen containing compound, a phosphorous containing compound, a sulfur containing compound, or a combination thereof. In yet other aspects, a capping ligand can comprise other compounds not specifically referenced. In one aspect, a capping ligand can comprise an aliphatic. In other aspects, a coating can comprise an alkyl chain, an aromatic compound, a heterocyclic compound, such as a heterocyclic amine, a phenyl moiety, and/or combinations thereof. In another aspect, a capping ligand can form a shell around at least a portion of any nanoparticles. In still another aspect, a capping ligand can form a shell around all or substantially all of the nanoparticles. In one aspect, a capping ligand can assist in the dispersion of nanoparticles in a solvent, such as, for example, to enable the formulation of inks or paints containing the nanoparticles. In another aspect, a nanoparticle can be coated with multiple layers, such as, for example, by a thin inorganic layer that is then surrounded by an organic capping ligand layer.

A coating material and/or capping ligand, can be selected so that all or a portion of the coating material and/or capping ligand can be removed during processing, film formation, after film formation, or during use. The specific method of removing a coating and/or capping ligand can vary depending upon the nature, composition, and binding of the coating material and/or capping ligand to the nanoparticle. Exemplary methods for removing a coating material and/or capping ligand can include thermal, chemical, optical methods, other methods and/or combinations thereof. Specific examples include thermal desorption, solvent washing, exposure to ozone and/or UV radiation.

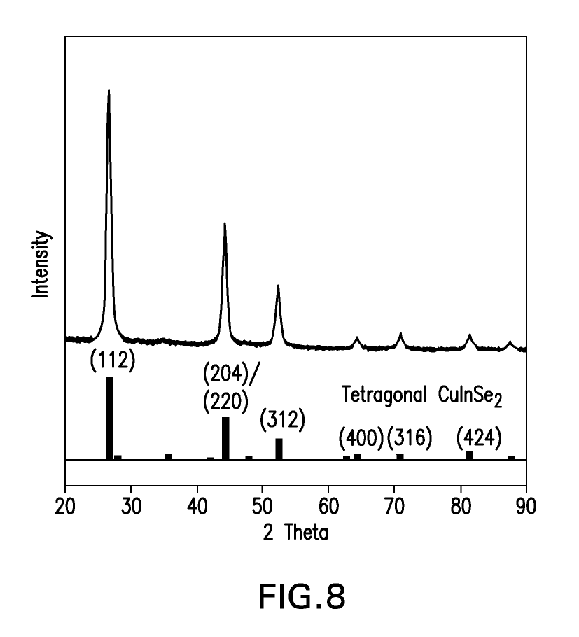

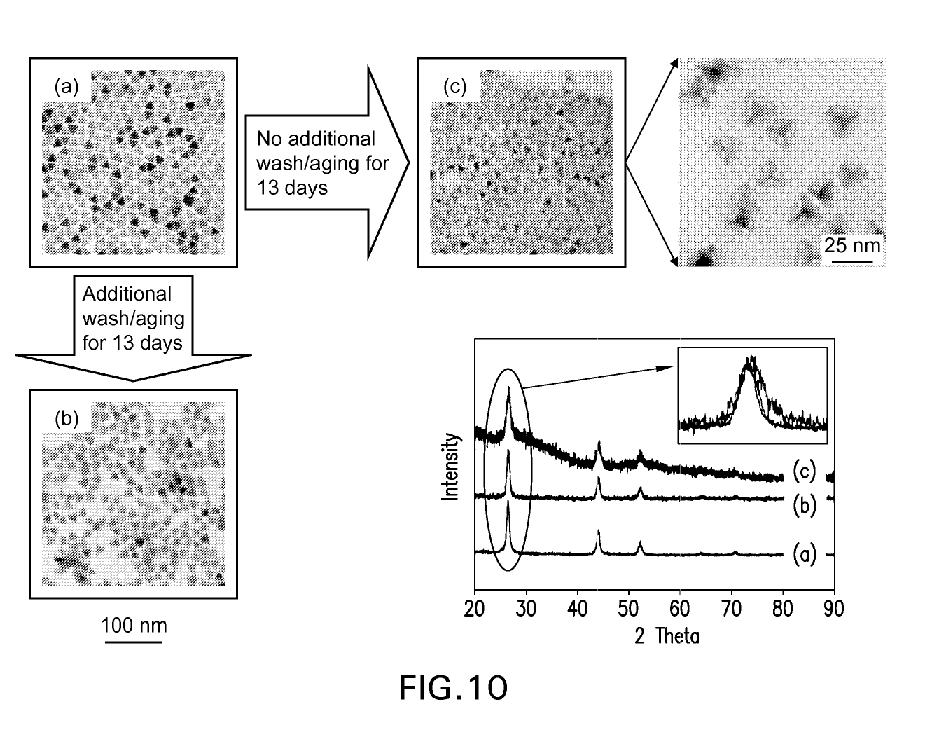

FIG. 10 shows the influence of aging on the shapes of the CuInSe₂ triangular nanoprisms. In various aspects, the CuInSe₂ nanoprisms or at least a portion thereof can maintain their shapes with aging. In one aspect, the nanoprisms can maintain their shape if they are washed (e.g. with ethanol) to remove excess organic surfactants (FIG. 10b). In other aspects, the nanoprisms can maintain their shape upon, for example, other treatment or no treatment. In one aspect, the nanoprisms or at least a portion thereof can change shape due to aging to show, for example, three edges in each prism when no washing is carried out (FIG. 10c). Without wishing to be bound by theory, the reaction between any excess oleylamine, if present, and the surface of a CuInSe₂ nanoprism, can result in etching on, for example, a wider side of a nanoprism. Three edges of the nanoparticles in FIG. 10c confirmed that the original CuInSe₂ triangular nanoparticles were three-dimensionally prism-shaped. XRD patterns, such as in FIG. 8, reveal that the three kinds of nanoparticles were tetragonal CuInSe₂.

Nanoparticles of the present invention can, in various aspects, be from about 1 nm to about 100 nm in diameter, or from about 1 nm to about 50 nm. In one aspect, exemplary nanoparticles can be from about 6 nm to about 20 nm, for example, about 6, 7, 8, 9, 10, 12, 14, 15, 16, 18, or 20 nm. Other nanoparticles can be smaller, for example as small as 5 nm or smaller. A batch of nanoparticles can have a variety of size distributions. A batch of nanoparticles can have distributional properties and any one or more nanoparticles can comprise a same or different size. For example, if a nanoparticle batch comprises sizes of from about 6 nm to about 20 nm, then a nanoparticle within that batch can correspond to any size within the range, such as, for example, about 6, 7, 8, 9, 10, 11, 12, 13, 14, 15, 16, 17, 18, 19, or 20 nm. Depending on the size distribution, a nanoparticle batch can be classified as polydisperse, monodisperse, or substantially monodisperse.

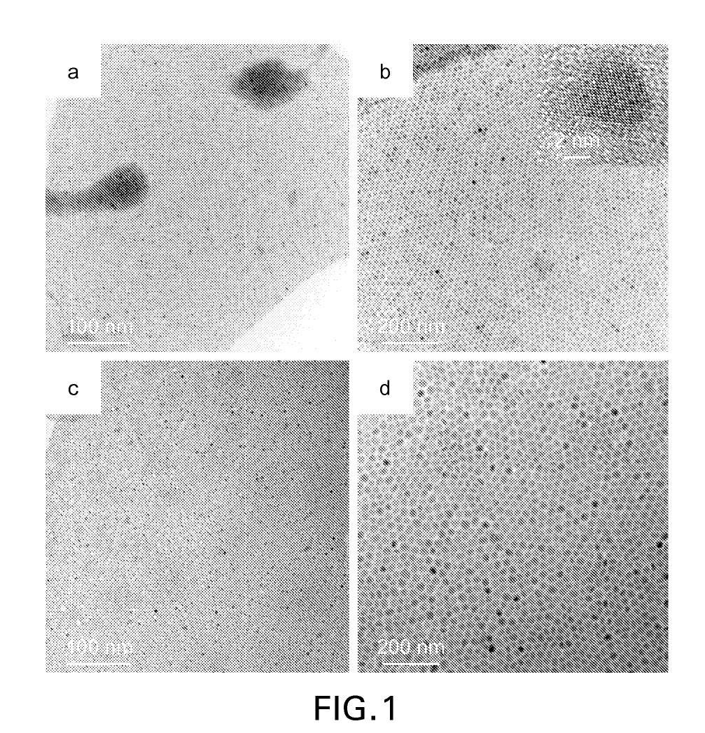

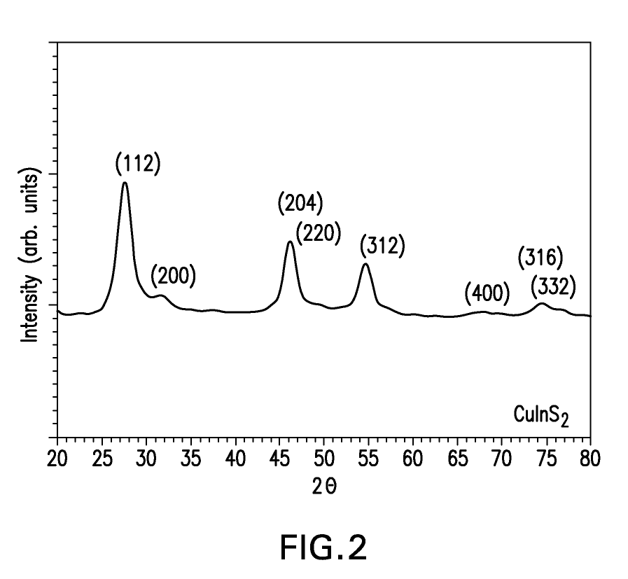

In an exemplary aspect, CuInS₂ nanocrystals comprising a chalcopyrite particle form can have a narrow size distribution that can be tuned by varying the oleyamine (OLA):metal precursor ratio. By varying the OLA:metal precursor ratio, for example, from between about 6:1 to about 1:1, nanocrystal size can be altered from about 6 nm to about 20 nm, as shown in FIG. 1. For an exemplary nanoparticle of about 8 nm in size, XRD showed exclusively copper indium sulfide (FIG. 2). By EDS, the nanocrystal composition matches Cu:In:S ratio of the precursors (1:1:2) within the error of the EDS detector (approx. ±2 at. %). The particular ratios described herein are intended to be exemplary and the present disclosure is intended to cover all suitable ratios and/or combinations of components.

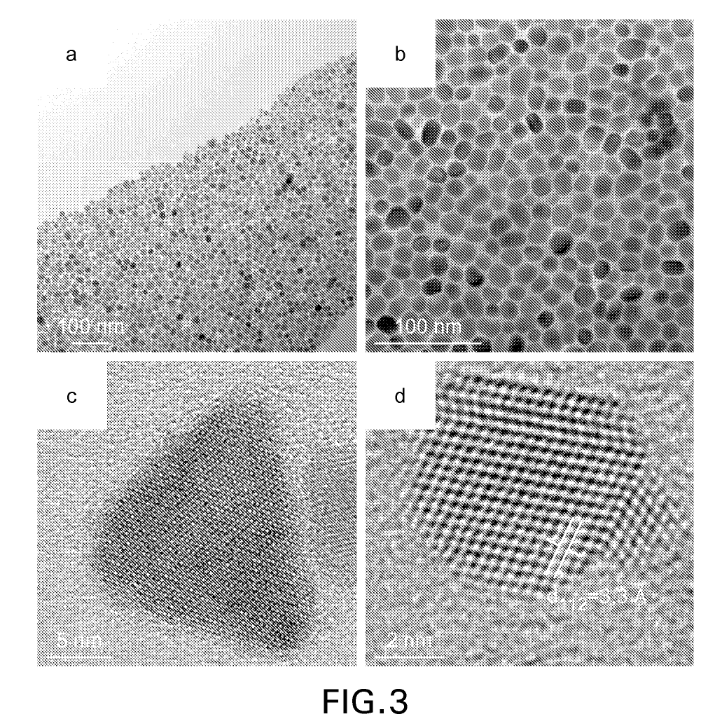

In another aspect, CIGS nanocrystals can be about 15 nm in diameter, or can have an average size of about 15 nm with some particles being as small as about 5 nm. FIG. 3d shows a high resolution image of a CuInS₂ nanocrystal with a (112) interplanar spacing of 3.3 Å which corresponds with the bulk value (3.35 Å) (PDF #00-040-1487). Powder XRD of CuInSe₂ (FIG. 4a) and CuGaSe₂ match those of bulk chalcopyrite CuInSe₂ and CuGaSe₂, respectively, with peak broadening due to nanometer grain-size. FIGS. 4b and 4c show the XRD patterns of CIGS nanocrystals with In:Ga ratios of about 75:25 and about 50:50, respectively. The peaks shift rightward in 20 with increasing Ga content, which corresponds to a decrease in lattice spacing caused by substituting smaller. Ga for larger In atoms.

It should be appreciated that the disclosed nanoparticle sizes can be determined by optical characterization, among other methods, and that the disclosed sizes can correspond to a physically measured value and not necessarily to the actual nanoparticle size.

### Films Comprising Nanoparticles

Nanoparticles disclosed herein can be incorporated into a film (e.g. a thin film). Films can be coated onto any appropriate substrate at any temperature (e.g. room temperature). Example substrates include, without limitation, glass, Mo-coated glass, non-woven indium tin oxide (ITO), transparent conducting material, quartz, paper, polymer material, metal, nanowire, nanotubes, metal alloy, or any other suitable material. In one aspect, a substrate can be electrically conductive, for example, to carry charge to or from a film or layer of nanoparticles. Films can be produced through a variety of methods; including spin coating, dip coating, drop casting, painted, sprayed, deposited, and solution or printing processing (e.g. ink-jet printing). In a specific aspect, nanoparticles can be dip coated onto a substrate. In another specific aspect, nanoparticles can be printed, such as, for example, with an ink jet printer. In one aspect, one or more nanoparticles can be coated onto and/or at least partially embedded into a polymeric material. In another aspect, one or more nanoparticles can be used to make a hybrid layer of nanoparticle(s) in an organic material or organic matrix.

Various solvents can be used to drop cast a nanoparticle dispersion onto a substrate including, without limitation, chloroform, tetrachloroethylene, decane, methyl isopropyl ketone, dicholorobenzene, butyl ether, and octane, among others. In one aspect, a plurality of nanoparticles can be assembled or allowed to assemble in an at least partially ordered array. In another aspect, a plurality of nanoparticles can form a self assembled ordered array. Such an at least partially ordered array can comprise a monolayer, a multilayer material, and can vary in thickness depending upon the number of layers, specific nanoparticles, and/or optional matrix material.

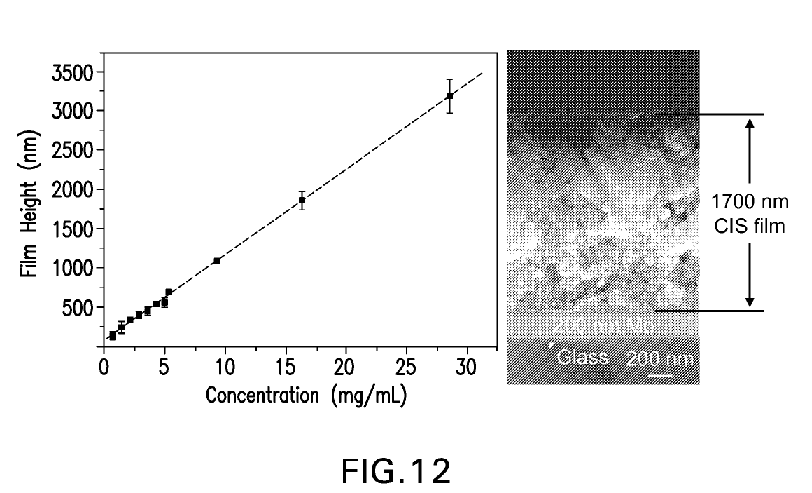

By changing the nanocrystal concentration in a solution, film thickness, for example, can be varied and/or tuned. In one aspect, a substantially linear relationship between the concentration of the nanoparticle solution used for drop-casting and the resulting film thickness can be observed. Thus, a specific film thicknesses can, for example, be targeted by controlling the concentration of the solution from which the films are cast. FIG. 12 shows this relationship for exemplary films dropcast from a solution of CuInSe₂ in tetrachloroethylene.

Drop casting can be carried out from a low-volatility solvent to reduce or prevent small and large cracks in a film. Films drop cast from tetrachloroethylene and decane, for example, can comprise few, if any, cracks. In one aspect, a film can be continuous across at least a portion of a substrate. In another aspect, a film can be discontinuous and cover one or more discrete regions on at least a portion of a substrate. In other aspects, a film can be resistant to or substantially resistant to cracking, spalling, and/or flaking.

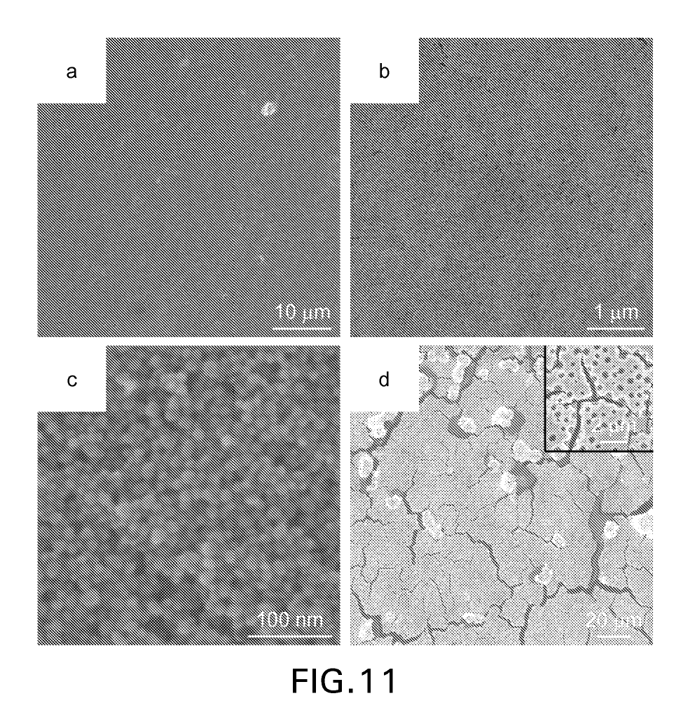

As-synthesized nanocrystals were dispersible in a variety of organic solvents. In one aspect, by dropcasting nanocrystals from high-boiling point organic solvents such as tetrachloroethylene, highly uniform, substantially defect-free films can be formed. In another aspect, CuInS₂ or CIGS nanocrystals can be dropcast onto, for example, a 12 mm by 25 mm soda-lime glass or Mo-coated glass substrate of the same size from a known concentration of nanocrystals. The substrate can then be placed in, for example, a vacuum oven and dried, for example, about 12 hours, to produce a uniform, continuous film. By changing, for example, the nanocrystal concentration, various thicknesses can be achieved. FIG. 11(a-c) shows a CuInSe₂ nanocrystal film produced by this method showing few defects. It should be appreciated that if a nanocrystal film is dropcast from a conventional low-boiling organic solvent, the resulting film can be discontinuous and full of cracks, as shown in FIG. 11d. It should be noted that the specific handling and, for example, drying steps as described herein can vary and one of skill in the art could readily select an appropriate handling and/or drying technique for a given material and/or application. As such, the present disclosure is not limited to any particular handling and/or drying technique or procedure.

Certain method, such as, for example, drop casting methods can be scaled up to create multiple films at once. For example, an array of substrates of about 0.5 in² in area can be place onto a sample holder, and about 150 μL of nanoparticle solution (e.g. at a concentration of 5 mg/mL) can be dropped onto each substrate. Subsequently, the array of substrates can be dried.

Alternatively, nanoparticles disclosed herein can be processed onto a substrate through inkjet printing. Substrates compatible with this method include, without limitation, paper, plastic, and indium tin oxide (ITO), other suitable substrates and/or combinations thereof. Any suitable printer can be used, such as, for example, a Fujifilm DIMATIX™ inkjet printer if an inkjet printing process is employed.

It should be appreciated that drop casting nanoparticles disclosed herein from a chloroform solution can result in cracking and non-uniform films. However, dip coating from chloroform can result in substantially crack-free, uniform films. For example, a nanoparticle dispersion of, for example, about 40 mg/mL in chloroform can be processed onto a substrate at a speed of about 1 mm/min to produce a crack-free, uniform film of about 200 to about 300 nm in thickness. The particular solvent composition, dip coating solution, and procedure, such as, for example, speed, can vary depending upon the particular components, solvents, and apparatuses, and one of skill in the art could readily select an appropriate solution, concentration, and/or speed, for example, for a given application.

The methods disclosed herein can produce films of varying thickness. In one aspect, a film thickness can range from about 1 to about 3500 nm. For example, if a lower concentration or nanoparticle solution (e.g. less than about 10 mg/mL) is used for film deposition, then films ranging from about 1 to about 1500 nm can be produced, such as, for example, films about 10, 20, 30, 40, 50, 60, 70, 80, 100, 200, 300, 400, 500, 600, 700, 800, 900, 1000, 1300, and 1500 nm thick. Alternatively, more concentrated (e.g. above about 10 mg/mL, up to for example, 30 mg/mL) nanoparticle dispersions can be used to deposit films with thicknesses ranging from about 1500 nm to about 3500 nm, for example, films with thicknesses of about 2000, 2500, 3000, and 3300 nm. In other aspects, a film thickness of less than about 1 nm or greater than about 3500 nm can be produced.

Films produced by the methods disclosed herein can be, for example, resistant films or conductive films. In another aspect, a film can be semi-conductive, In yet other aspects, a film can have a varying conductivity, for example, across points on the surface thereof. For example, the resistance of as-cast films can be about 1 kΩ·cm before any further treatment. This value is two to three orders of magnitude higher than the reported resistance desired to produce an efficient photovoltaic device. It should be appreciated, however, that by removing organic ligands from a film and sintering nanoparticles together, an increase in, for example, conductivity can be obtained. To achieve this, a variety of film treatments can be carried out and the resulting properties of the nanocrystal films can be characterized.

To remove ligands from a film, for example, at least four routes known in the art can be used: thermal annealing, UV-ozone treatment, oxygen plasma treatment, and chemical treatments.

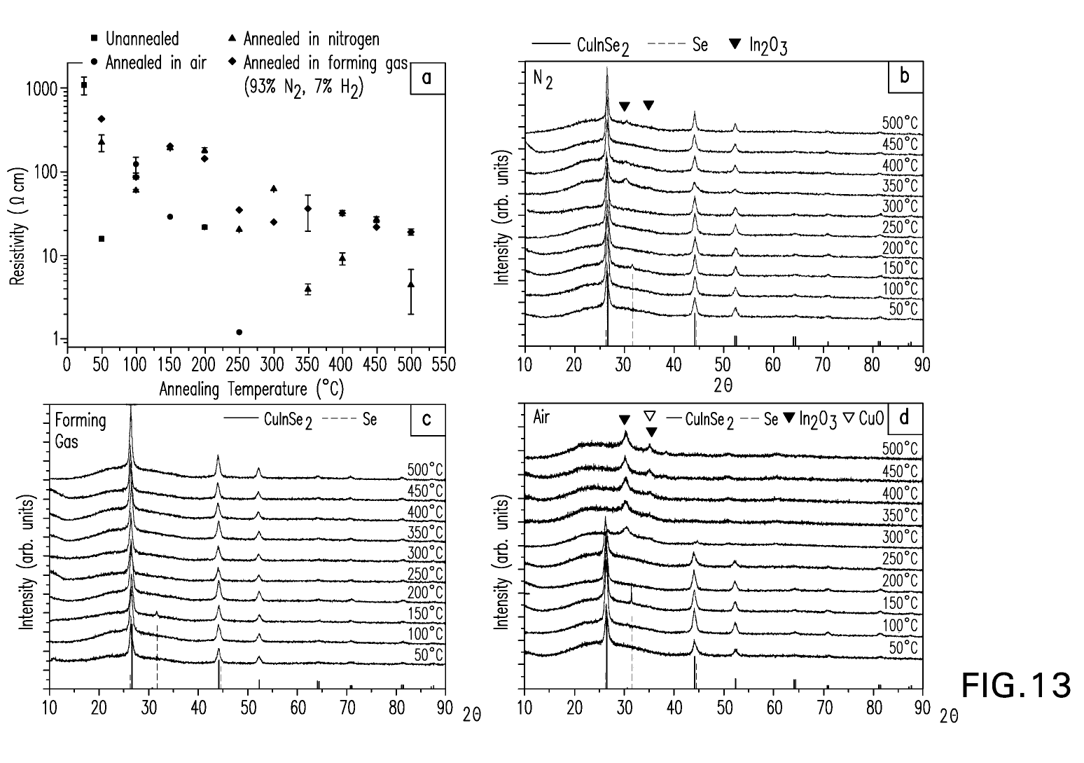

CIS films, for example, annealed under different gases can exhibit similar changes in conductivity, except for those annealed in air, as shown in FIG. 13a. By heating the films to temperatures as low as about 250° C., the resistivity can, for example, drop by about two orders of magnitude. Films annealed in air can form oxide when annealed over 250° C., as shown by the XRD patterns in FIG. 13a, and the resistivity can increase by several orders of magnitude, to a non-measurable level.

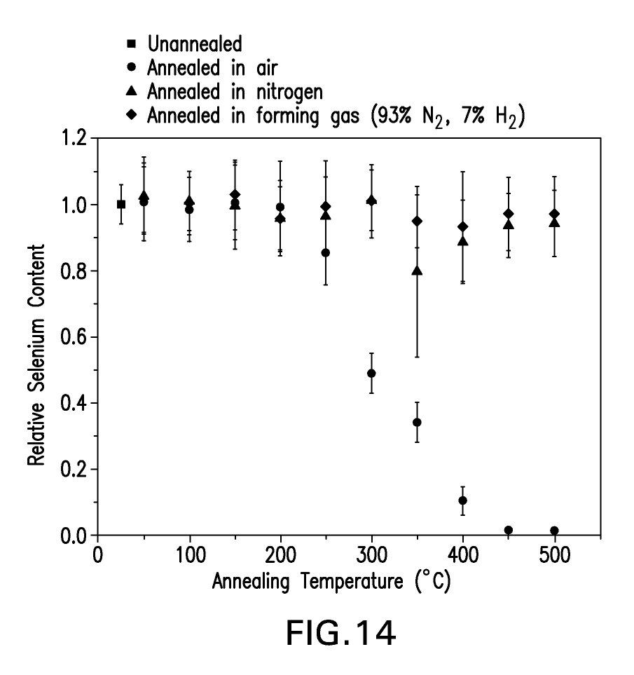

Film annealing under forming gas, a slightly reducing environment, can result in no new phase formation (FIG. 12c). In CIGS manufacturing, a concern is degassing of selenium during heating steps. To monitor this event, the composition can be measured at every annealing condition, for example, as shown in FIG. 14. In one aspect, a film can be annealed under a selenium containing atmosphere.

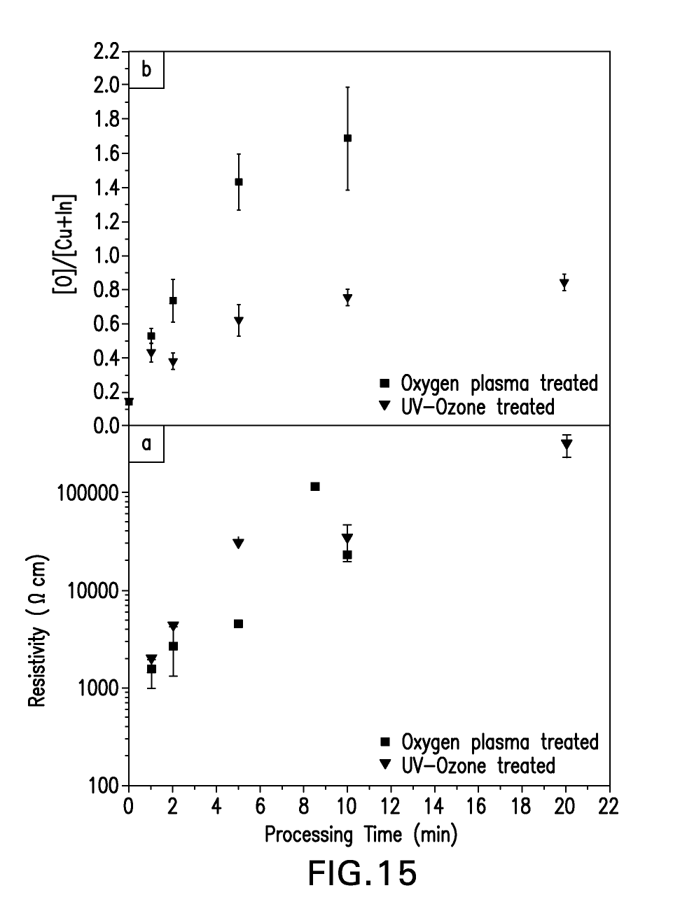

UV-ozone and oxygen plasma are also common techniques used in the semiconductor industry to reactively remove organics. Treating the CIS nanocrystal films under oxygen plasma or UV-ozone can result in no formation of oxides or other phases by X-ray diffraction. However, the film resistance can increase with increased exposure to these treatments, as shown in FIG. 15a. EDS of the treated films (FIG. 15b) indicates that the level of oxygen increases during this treatment as it reacts with the nanocrystal surfaces, presumably forming an amorphous oxide layer.

### Devices Comprising Nanoparticles

Nanoparticles of the present invention can be incorporated into electronic and photonic devices, such as, for example, a photovoltaic device. An exemplary photovoltaic device is a solar cell. The absorber layer in a solar cell, for example, can comprise nanoparticles disclosed herein. Other devices that can incorporation the nanoparticles of the present invention include printable electronic applications, such as transistors and photodetectors. In one aspect, a device can be constructed, wherein one or more nanoparticles can be utilized as a precursor for making, for example, a film or layer. In an exemplary aspect, a plurality of nanoparticles can be deposited and then at least partially fused together to form a film, wherein the at least partially fused film is no longer made of individual nanoparticles. While such a film no longer contains any or any substantial number of individual nanoparticles, the properties of the produced film can be at least partially dependent on the properties of the nanoparticle precursors utilized to form the film. A film of fused or partially fused particles can, in various aspects, be formed by heating the nanoparticles to a temperature sufficient to at least partially fuse together. In various aspects, such a temperature can range from ambient up to about 100, 150, 200, 250, 300, 350, 400, 450, 500, 550, 600, 650° C. or higher. In one aspect, a plurality of nanoparticles can be heated to a temperature of up to about 250° C. In another aspect, a plurality of nanoparticles can be heated to a temperature of up to about 600° C.

A nanoparticle film disclosed herein, for example, can be used as a layer in a photovoltaic device. Such a device could be flexible, for example, if a nanoparticle layer were coated onto a flexible substrate, such as, for example, plastic.

A stoichiometry controlled absorber layer can be created for use with a photovoltaic device by controlling nanocrystal stoichiometry (i.e. the relative amounts of the materials making up the nanoparticle). A photovoltaic device could comprise, for example, a nanocrystal layer with a composition gradient. A film with a GaₓIn₁₋ₓ concentration gradient, for example, could be created such that x varies from about 0 to about 1 through the film.

In various aspects, a layer can be electrically conductive or electrically insulating.

In other aspects, a layer can comprise nanoparticles, such as those described herein; comprising a ternary composition, a quaternary composition, or a combination thereof.

In one aspect, a layer can be absorbing, such as, for example, optically absorbing. Such a layer can be useful in, for example, absorbing visible light such as in a photovoltaic device. Such an absorbing layer can comprise any of the nanoparticles or a combination of nanoparticles, such as a plurality of non-spherical and/or substantially non-spherical nanoparticles and/or a self assembled array of nanoparticles described herein. In one aspect, a layer comprising nanoparticles has no or substantially no pores, pinholes, and/or defects. In another aspect, the number and size of pores, pinholes, and/or defects in a layer do not adversely affect the performance of the layer in a photovoltaic device.

In another aspect, the degree of light absorption of an absorbing layer can vary depending upon the size, range of sizes, and/or distribution of sizes of the nanoparticles comprising the layer. In yet another aspect, carrier multiplication can occur upon absorption of a photon by an absorbing layer.

In one aspect, an absorbing layer comprises a plurality of the nanoparticles described herein. In another aspect, a photovoltaic device can comprise an absorbing layer comprising a plurality of the nanoparticles described herein, and an anode and a cathode. In another aspect, a photovoltaic device can comprise an absorbing layer, a semiconducting buffer layer, and a cathode and an anode. In yet another aspect, a photovoltaic device can comprise an absorbing layer comprising any of the nanoparticles described herein and an organic semiconductor.

Photovoltaic devices can also be created with absorbing layers comprising controlled crystallographic orientations created by depositing nanocrystals with various non-spherical shapes, such as disks, that can self-assemble with a preferred crystallographic orientation.

A photovoltaic device can comprise a number of components and configurations, and the present invention is not intended to be limited to any particular device components and/or configurations. In various aspects, a photovoltaic device can comprise one or more absorbing layers, buffer layers, and/or metal contact layers. In another aspect, a photovoltaic device comprises at least two functional layers. In one aspect; at least one functional layer of a photovoltaic device is comprises nanoparticles as described herein that are printed, such as, for example, with an inkjet printer. In another aspect, at least two functional layers of a photovoltaic device comprise nanoparticles as described herein that are printed. In yet another aspect, each of the functional layers in a photovoltaic device comprise nanoparticles as described herein and are printed.

### EXAMPLES

The following examples are put forth so as to provide those of ordinary skill in the art with a complete disclosure and description of how the compounds, compositions, articles, devices and/or methods claimed herein are made and evaluated, and are intended to be purely exemplary of the invention and are not intended to limit the scope of what the inventors regard as their invention. Efforts have been made to ensure accuracy with respect to numbers (e.g., amounts, temperature, etc.), but some errors and deviations should be accounted for. Unless indicated otherwise, parts are parts by weight, temperature is in ° C. or is at ambient temperature, and pressure is at or near atmospheric.

1. CuInS₂ Nanocrystal Synthesis

An exemplary reaction was carried out by adding 0.26 g (1 mmol) of Cu(acac)₂ and 0.41 g (1 mmol) of In(acac)₃ to 7 mL of DCB in a 25 mL three-neck flask under ambient conditions. In a separate 25-mL three-neck flask, 0.064 g (2 mmol) of elemental sulfur was dissolved in 3 mL of o-dichlorobenzene (DCB) under ambient conditions. The degassing of the reaction precursors were done using standard airless techniques with a Schlenk line. Both flasks are purged of oxygen and water by pulling vacuum at room temperature for 30 minutes, followed by bubbling with N₂ at 60° C. for 30 minutes. Between 0.5 and 2 mL (1.5 to 6 mmol) of OLA are added to the (Cu, In)-DCB mixture and both flasks are heated to 110° C. and combined, maintaining a N₂ flow. The reaction mixture is refluxed (182° C.) for one hour under N₂ flow.

2. CIGS Nanocrystal Synthesis

A. Polydisperse CIGS Nanocrystals

Large (greater than about 10 nm in diameter) nanocrystals were synthesized in a one-pot reaction in which 1 mmol of CuCl (0.10 g), 1 mmol combined of InCl₃ and GaCl₃, and 2 mmol of elemental Se (0.158 g) were added to a 25-mL three-neck flask in a nitrogen-filled glove box. The flask was removed from the glove box and connected to a Schlenk line, where 10 mL of OLA was injected into the flask. The flask was purged of oxygen and water by pulling vacuum at 60° C. for one hour, followed by bubbling with N₂ at 110° C. for one hour. The flask was heated to 240° C., and the reaction proceeded for four hours.

B. Monodisperse, CuInSe₂ Nanocrystals

To make smaller (less than about 10 nm diameter) CuInSe₂ nanocrystals, bis(trimethylsilyl)selenide was used as the selenium source. In a typical reaction 0.5 mmol of CuCl (0.05 g) and 0.5 mmol of InCl₃ (0.11 g) were combined in a 25 mL 3-neck flask. The flask was connected to a Schlenk line and 10 mL of OLA was injected into the flask. The flask was purged of water and oxygen as described previously, and the temperature was increased to 275° C., forming an optically clear, bright yellow metal-OLA complex. When the temperature reaches 275° C., 1 mmol (225 μL) BTMS was injected. The reaction flask immediately turns bright red, then dark brown. The reaction was carried out for four hours.

3. Synthesis of CuInSe₂ Nanoprisms

A mixture of 0.05 g of CuCl (0.5 mmol of Cu), 0.11 g of InCl₃ (0.5 mmol of 1n), and 10 mL of oleylamine was vigorously stirred and degassed in the reaction flask for 30 minutes at 60° C. through pulling vacuum in a Schlenk line. The mixture was heated to 130° C. under nitrogen. It was kept aged for 10 minutes until it turned from blue into yellow, indicating the formation of Cu- (or In-) oleylamine complex. Subsequently, the solution was cooled at 100° C. for the injection of selenium precursor. A selenium precursor reactant solution was prepared by dissolving 0.123 g of selenourea (1.0 mmol) in 1 mL of oleylamine at 200° C. The selenium precursor was injected into the Cu- (or In-) oleylamine complex at 100° C. The temperature was then immediately increased to 240° C., and the reaction proceeded for one hour.

4. Nanocrystal Purification

Nanocrystals were purified by precipitation with excess ethanol followed by centrifugation at 8000 rpm for 10 min. The supernatant contains unreacted precursor and byproducts and was discarded. The nanocrystals were redispersed in 10 mL of chloroform and centrifuged again at 1000 rpm for 5 min. Poorly capped nanocrystals and large particulates settle during centrifugation, whereas the well-capped nanocrystals remain dispersed. The precipitate was discarded. A small amount of OLA (0.2 mL) was added to the supernatant to maintain good surface passivation. To remove all excess capping ligands and any remaining impurities, the product was again precipitated using ˜5 mL of ethanol and centrifuged at 8000 rpm for 10 minutes, then redispersed in chloroform. This process was done three times to obtain a high-purity product. The isolated nanocrystals disperse in various organic solvents, including hexane, toluene, decane, chloroform, and TCE.

5. Nanocrystal Deposition and Film Formation.

Substantially defect-free, approximately 600 nm-thick films were obtained by dispersing nanocrystals in TCE at relatively high concentrations (5 mg/mL) and drop casting the dispersion on a glass or Mo-coated glass substrate. 150 μL of these dispersions were drop cast onto a 12×25 mm substrate. The nanocrystal suspension was evaporated in a vacuum chamber at room temperature for 12 hours to remove solvent and completely dry the film.

6. Annealing of Nanocrystal Films

The nanocrystal films were annealed using a variety of different approaches, including heating under controlled atmosphere, and treatment by UV-ozone and oxygen plasma. Films were heated by placing the nanocrystal-covered substrate inside a tube furnace equipped with a 1 in. inner diameter quartz tube under gas flows (N₂, or N₂/H₂ mixture) or under air by detaching the gas fittings and using room air as the environment. Thermal treatments were done for one hour with a 25° C./min. ramp rate to the setpoint temperature. Nanocrystal films were also treated with UV-ozone and oxygen plasma. Nanocrystal films were placed in a Jelight Model 42 UV-Ozone chamber approximately 1 cm from the UV lamp. The UV-ozone chamber is equipped with low-pressure Hg-vapor grid with a lamp intensity of 28 mW/cm². Films were treated for 1 to 20 minutes.

7. Materials Characterization

The nanocrystals and nanocrystal films were characterized using transmission electron microscopy (TEM), energy-dispersive x-ray spectroscopy (EDS), scanning electron microscopy (SEM), X-ray diffraction (XRD), thermogravimetric analysis (TGA), small-angle x-ray scattering (SAXS), and UV-Vis-NIR absorbance spectroscopy. Low-resolution TEM images were taken using a Phillips 208 TEM with 80 kV accelerating voltage. High-resolution TEM (HRTEM) images and EDS spectra were aquired using a JEOL 2010F TEM operating at 200 keV equipped with an Oxford INCA EDS. TEM samples were prepared by drop-casting a dispersion of nanocrystals in chloroform, hexane, or toluene onto a 200 mesh amorphous carbon-coated copper or nickel TEM grid (Electron Microscopy Sciences). SEM images were aquired using either a LEO 1530 SEM or a Zeiss Supra 40 VP SEM operating at 10 keV. The LEO 1530 SEM is equipped with an EDS detector which was used to analyze the composition of nanocrystal films. XRD was performed on a Bruker-Nonius D8 Advance θ-2θ Powder Diffractometer, with Cu Kα (λ=1.54 Å) radiation, a Bruker Sol-X Si(Li) solid-state detector, and a rotating stage. For XRD of the as-synthesized nanocrystals, the nanocrystals were evaporated from a concentrated dispersion onto a quartz (0001) substrate to obtain a ˜0.5 mm thick film. Diffraction data was collected by scanning for 4 to 12 hours with an angle increment of 0.01° or 0.02°, a scan rate of 6°/min., and a rotation speed of 15 rpm. TGA was done with a Perkin-Elmer TGA 7 with a platinum sample dish. Small-angle X-ray scattering (SAXS) was performed on a Molecular Metrology system with a rotating copper anode X-ray generator (Bruker Nonius; λ=1.54 Å) operating at 3.0 kW. The scattered photons were collected on a 2D multiwire gas-filled detector (Molecular Metrology, Inc.) and the scattering angle was calibrated using a silver behenate (CH₃(CH₂)₂₀COOAg) standard. Absorbance spectroscopy was performed using a Varian Cary 500 UV-Vis-NIR spectrophotometer, using hexane-dispersed nanocrystals in a quartz cuvette. Electrical characterization was done using a Karl Suss Probe Station and an Agilent 4156C Parameter Analyzer. Film thicknesses were found using profilometer.

8. Inkjet Printing

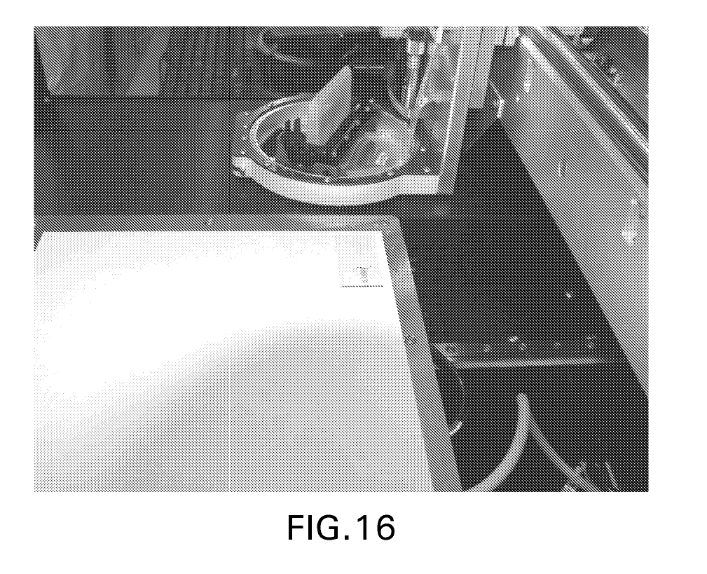

CIGS nanocrystals dispersed in TCE were printed onto glass, silicon, and paper using a FUJIFILM Dimatix inkjet printer. Using a 40 mg/mL dispersion of nanocrystals, uniform patterns without defects could be formed with submillimeter resolution. It is feasible to print fine grids with high resolution and desired thicknesses. FIG. 16 shows the device in operation printing a sample grid pattern.

9. Photovoltaic Device Comprising CIGS

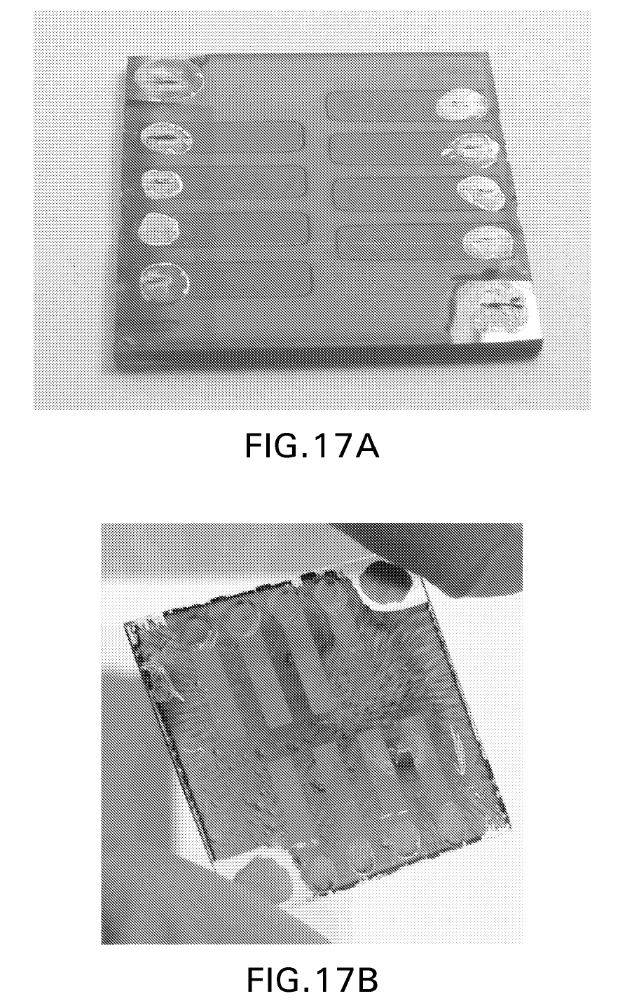

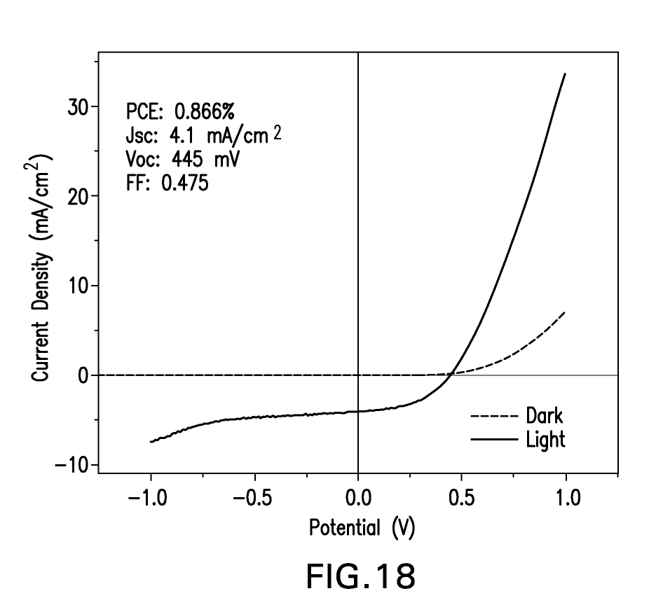

Substrate CIGS photovoltaic devices were constructed using a conventional structure shown in FIG. 17. CuInSe₂ nanocrystals were solution deposited on top of a sputtered molybdenum back contact in place of the conventional vapor-deposited layer. After depositing and drying the nanocrystal film, a ˜20 nm CdS buffer layer was deposited by chemical bath deposition. The top contacts to the device were completed by sputtering 50 nm of ZnO and 300 nm of Al-doped ZnO. On average, CIGS devices built through methods described above have a fill factor of about 0.3, an open circuit voltage of about 50 mV and a short circuit current of about 10 μA/cm² under 1.5 AM solar illumination. Such characteristics correspond to an efficiency of about 10⁻⁴%. FIG. 18 shows the typical IV characteristics of such a device.

It will be apparent to those skilled in the art that various modifications and variations can be made in the present invention without departing from the scope or spirit of the invention. Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A nanoparticle comprising at least three of: copper, indium, gallium, sulfur, selenium, tellurium, or a combination thereof.

2. The nanoparticle of claim 1, having a diameter of from about 1 nm to about 100 nm.

3. The nanoparticle of claim 1, wherein the nanoparticle is a ternary composition.

4. The nanoparticle of claim 1, wherein the nanoparticle is a quaternary composition.

5. The nanoparticle of claim 1, wherein the nanoparticle comprises a uniform or substantially uniform composition.

6. The nanoparticle of claim 1, comprising at least one of CuInSe₂, CuInS₂, CuInₓGa₁₋ₓSe₂, CuInTe₂, CuGaTe₂, CuGaₓIn₁₋ₓTe₂, Cu₂ZnSnS₂, Cu₂ZnSnS₄, Cu₂ZnSnSe₄, or Cu(InₓGa₁₋ₓ)Se₂, or a combination thereof, wherein x is from 0 to 1.

7. The nanoparticle of claim 1, wherein the nanoparticle is non-spherical.

8. The nanoparticle of claim 1, wherein the nanoparticle comprises a tetrahedron shape, a triangular shape, or a prismatic shape.

9. The nanoparticle of claim 1, wherein the nanoparticle is semi-conducting.

10. The nanoparticle of claim 1, further comprising at least one dopant.

11. The nanoparticle of claim 1, further comprising a coating.

12. The nanoparticle of claim 11, wherein the coating comprises an inorganic material, an organic material, or a combination thereof.

13. The nanoparticle of claim 11, wherein the coating comprises a metal.

14. The nanoparticle of claim 11, wherein the coating comprises at least one organic capping ligand.

15. The nanoparticle of claim 11, wherein the coating provides dispersibility of the nanoparticle in an ink vehicle.

16. The nanoparticle of claim 11, wherein the coating is electrically conductive.

17. The nanoparticle of claim 11, wherein the coating comprises at least one conjugated molecule.

18. The nanoparticle of claim 11, wherein the coating is electrically insulating.

19. The nanoparticle of claim 11, wherein the coating comprises at least one of an alkane, aliphatic, heterocyclic amine, phenyl moiety, or a combination thereof.

20. The nanoparticle of claim 11, wherein at least a portion of the coating is capable of being removed after the formation of a film.

21. The nanoparticle of claim 1, wherein the nanoparticle comprises at least one of copper indium gallium selenide, a copper indium sulfide, or a combination thereof.

22. The nanoparticle of claim 21, wherein the nanoparticle is capable of being drop-cast, dip-coated, spin-coated, painted, sprayed, deposited, or printed onto a substrate, or a combination thereof.

23. The nanoparticle of claim 1, wherein the nanoparticle is at least partially crystalline.

24. The nanoparticle of claim 1, wherein the nanoparticle is a nanocrystal.

25. An ink comprising a plurality of the nanoparticle of claim 1.

26. The ink of claim 25, wherein the ink is capable of being drop-cast, dip-coated, spin-coated, painted, sprayed, deposited, or printed onto a substrate, or a combination thereof.

27. The ink of claim 25, wherein the ink is printable.

28. A film comprising a plurality of the nanoparticles of claim 1.

29. The film of claim 28, wherein at least a portion of the plurality of nanoparticles comprises at least one of CuInSe₂, CuInS₂, CuInₓGa₁₋ₓSe₂, CuInTe₂, CuGaTe₂, CuGaₓIn₁₋ₓTe₂, Cu₂ZnSnS₂, Cu₂ZnSnS₄, Cu₂ZnSnSe₄, or Cu(InₓGa₁₋ₓ)Se₂, or a combination thereof, wherein x is from 0 to 1.

30. The film of claim 28, wherein at least a portion of the nanoparticles are fused.

31. The film of claim 28, having a predetermined stoichiometry.

32. The film of claim 28, having a stoichiometry matching or substantially matching a stoichiometry of at least a portion of the nanoparticles.

33. The film of claim 28, wherein the film comprises a composition gradient through at least a portion of the film.

34. The film of claim 28, wherein at least a portion of the film has a crystallographic orientation at least partially determined by the shape of at least a portion of the nanoparticle disposed therein.

35. The film of claim 28, wherein the film is resistant to or substantially resistant to cracking, spalling, and/or flaking during formation of the film and use.

36. A layer comprising a plurality of nanocrystals comprising at least one of a copper indium gallium selenide, a copper indium sulfide, a copper indium selenide, or a combination thereof.

37. A layer comprising a plurality of nanocrystals comprising Cu₂ZnSnS₄.

38. The layer of claim 36, wherein at least a portion of the nanocrystals comprise a coating.

39. The layer of claim 36, wherein at least a portion of the layer is electrically conductive.

40. The layer of claim 36, wherein at least a portion of the layer is electrically insulating.

41. The layer of claim 36, wherein at least a portion of the nanoparticles comprise a ternary composition, a quaternary composition, or a combination thereof.

42. The layer of claim 36, wherein the layer is optically absorbing.

43. The layer of claim 36, wherein at least a portion of the nanoparticles comprise CuInSe₂.

44. The layer of claim 36, comprising a composition gradient through at least a portion of the layer.

45. A method for making a nanoparticle composition, the method comprising contacting a copper precursor, an indium precursor, sulfur and/or a sulfur containing species, and an aliphatic amine.

46. The method of claim 45, wherein the aliphatic amine is a component of a solvent.

47. The method of claim 45, wherein the aliphatic amine comprises oleylamine.

48. The method of claim 45, wherein at least at least a portion of the copper precursor, indium precursor, sulfur and/or sulfur containing species are degassed and/or sparged with an inert gas.

49. The method of claim 45, further comprising heating the mixture.

50. The method of claim 45, wherein at least two of the copper precursor, indium precursor, and sulfur and/or sulfur containing species are contacted separate from any remaining components prior to contacting with the aliphatic amine.

51. The method of claim 45, wherein the copper precursor and indium precursor are first contacted with a solvent to form a first mixture; wherein sulfur and/or a sulfur containing species are separately contacted with a same or different solvent to form a second mixture; wherein the aliphatic amine is contacted with the first mixture; and wherein the first mixture and the second mixture are contacted.

52. The method of claim 51, further comprising heating at least one of the first mixture, the second mixture, or a combination thereof.

53. A method for making a nanoparticle composition, the method comprising contacting a copper precursor, an indium precursor, a gallium precursor, a selenium precursor and an aliphatic amine.

54. The method of claim 53, wherein at least two of the copper precursor, indium precursor, gallium precursor, and selenium precursor are contacted separate from any remaining components prior to contacting with the aliphatic amine.

55. The method of claim 53, wherein at least a portion of the copper precursor, indium precursor, gallium precursor, and selenium precursor are degassed and/or sparged with an inert gas.

56. The method of claim 53, further comprising heating the contacted composition.

57. The method of claim 53, wherein the aliphatic amine comprises oleylamine.

58. The method of claim 53, wherein the copper precursor, indium precursor, gallium precursor, and selenium precursor are contacted prior to contacting with the aliphatic amine.

59. The method of claim 53, wherein the copper precursor, indium precursor, and gallium precursor are first contacted to form a mixture, wherein the mixture is contacted with the aliphatic amine to form a second mixture, and wherein the second mixture is then contacted with a selenium precursor.

60. The method of claim 59, wherein the second mixture is degassed and/or sparged with an inert gas prior to contacting with a selenium precursor.

61. The method of claim 45, wherein at least one of the shape and/or size of at least a portion of the nanoparticle composition can be controlled.

62. The method of claim 45, wherein the copper precursor comprises Cu(acac)₂, CuCl, or a combination thereof.

63. The method of claim 45, wherein the indium precursor comprises In(acac)₃, InCl₃, or a combination thereof.

64. The method of claim 45, wherein the gallium precursor comprises GaCl₃, Ga(acac)₃, or a combination thereof.

65. The method of claim 45, wherein the selenium precursor comprises at least one of elemental selenium, selenourea, bis(trimethylsilyl)selenide, or a combination thereof.

66. The method of claim 46, wherein the solvent comprises dichlorobenzene.

67. The method of claim 45, wherein the nanoparticle composition is further at least partially purified by precipitation with a solvent.

68. The method of claim 45, wherein at least a portion of the nanoparticle composition comprises a chalcopyrite crystal structure.

69. A nanoparticle composition formed by the method of claim 45.

70. A method for making an ink, comprising contacting a plurality of the nanoparticles of claim 1 one or more solvents.

71. A method of preparing a film, the method comprising contacting a plurality of the nanoparticles of claim 1 with a substrate.

72. The method of claim 71, wherein the plurality of nanoparticles are disposed in a solvent as an ink.

73. The method of claim 71, wherein contacting comprises an inkjet technique.

74. The method of claim 71, wherein the substrate comprises paper, polymer, non-woven, metal, metal alloy, nanowire, nanotubes, indium tin oxide, transparent conducting substrate, or a combination thereof.

75. The method of claim 71, wherein the substrate is electrically conductive.

76. The method of claim 71, further comprising, after contacting, annealing the nanoparticles at a temperature of up to about 600° C.

77. The method of claim 76, wherein annealing is at a temperature of up to about 250° C.

78. The method of claim 76, wherein annealing is performed in a selenium containing atmosphere.

79. The method of claim 71, further comprising selecting one or more nanoparticles having a predetermined shape, and then contacting the nanoparticles such that the resulting film has a desired crystallographic orientation.

80. The method of claim 71, wherein at least a portion of the nanoparticles comprise a coating, and further comprising, after contacting, removing at least a portion of the coating from at least a portion of the nanoparticles.

81. The method of claim 71, further comprising assembling a photovoltaic device comprising the nanoparticles contacted with the substrate.

82. A photovoltaic device comprising a plurality of the nanoparticles of claim 1.

83. The photovoltaic device of claim 82, wherein at least a portion of the nanoparticles are disposed within a film, a layer, or a combination thereof.

84. The photovoltaic of claim 82, wherein at least a portion of the device is flexible or is positioned on at least a portion of a flexible substrate.

85. The photovoltaic device of claim 82, comprising a light absorbing layer.

86. The photovoltaic device of claim 85, wherein the light absorbing layer comprises no or substantially no pores.

87. The photovoltaic device of claim 85, wherein at least a portion of the light absorbing layer comprises a controlled crystallographic orientation.

88. The photovoltaic device of claim 85, wherein the absorbing layer comprises a plurality of non-spherical and/or substantially non-spherical self-assembled nanoparticles.

89. The photovoltaic device of claim 85, wherein the absorbing layer comprises a composition gradient through at least a portion of the absorbing layer.

90. The photovoltaic device of claim 85, wherein the absorbing layer comprises a uniform or substantially uniform composition through at least a portion of the absorbing layer.

91. The photovoltaic device of claim 82, comprising a buffer layer.

92. The photovoltaic device of claim 82, comprising at least two functional layers.

93. The photovoltaic device of claim 92, wherein at least one of the two functional layers comprises a light absorbing layer, a metal contact layer, or a combination thereof.

94. The photovoltaic device of claim 92, wherein each functional layer within the device is printed from an ink.

95. The photovoltaic device of claim 85, wherein the light absorbing layer comprises a plurality of nanoparticles comprising at least three of copper, indium, gallium, sulfur, selenium, tellurium, or a combination thereof.

96. The photovoltaic device of claim 85, further comprising a cathode and an anode.

97. The photovoltaic device of claim 85, further comprising a semiconducting buffer layer.

98. The photovoltaic device of claim 95, wherein the light absorbing layer further comprises an organic semiconductor.
